(19) United States
(12) Patent Application Publication
(10) Pub. No.: US 2025/0247075 A1
(43) Pub. Date: Jul. 31, 2025

(54) VIBRATOR

(71) Applicant: SEIKO EPSON CORPORATION, Tokyo (JP)

(72) Inventor: Kimio NAGASAKA, HOKUTO-SHI (JP)

(21) Appl. No.: 19/037,214

(22) Filed: Jan. 26, 2025

(30) Foreign Application Priority Data
Jan. 26, 2024 (JP) 2024-009984
Mar. 7, 2024 (JP) 2024-035225

(51) Int. Cl. H03H 9/17; H03H 9/02; H03H 9/05; H03H 9/13

(52) U.S. Cl. CPC H03H 9/176; H03H 9/02031; H03H 9/0211; H03H 9/0595; H03H 9/132

(57) ABSTRACT

A vibrator using a piezoelectric body made of a zinc blende type single crystal includes a vibrating portion having a ring shape and having a plurality of first vibrating portions and a plurality of second vibrating portions alternately arranged in at least a part of the ring shape, wherein the vibrating portion includes first electrodes provided respectively to the plurality of first vibrating portions, second electrodes provided respectively to the plurality of second vibrating portions, a first coupling portion electrically coupling the first electrodes to each other, and a second coupling portion electrically coupling the second electrodes to each other, and the plurality of first electrodes and the plurality of second electrodes are alternately arranged on a plane perpendicular to a axis of the single crystal.

The present application is based on, and claims priority from JP Application Serial Number 2024-009984, filed Jan. 26, 2024, and JP Application Serial Number 2024-035225, filed Mar. 7, 2024, the disclosure of which are hereby incorporated by reference herein in their entirety.

### BACKGROUND

### 1. Technical Field

The present disclosure relates to a vibrator.

### 2. Related Art

In the past, there have been known various vibrators that vibrate a vibrating portion using a plurality of unit vibrators. For example, JP-A-2002-111434 discloses a Lame-mode quartz crystal vibrator in which a plurality of small vibrating portions is arranged two-dimensionally.

JP-A-2002-111434 is an example of the related art.

In the Lame-mode quartz crystal vibrator in JP-A-2002-111434, the vibrator vibrates at equivalent intensities in two directions, namely a row direction which is one arrangement direction of the two-dimensional arrangement and a column direction which is a direction orthogonal to the row direction. Here, the resonance frequencies corresponding to these two directions depend on the width dimension of the vibrating portion. For this reason, in order to vibrate in those two directions in a coordinated manner, it is necessary to make the dimensions in the row direction and the column direction of the vibrating portion coincide with each other. However, since when increasing the resonance frequency, the wavelength making a contribution to the resonance shortens, when the resonance frequency is high, there is a possibility that the vibration intensity decreases due to an error in processing accuracy and so on. When the vibration intensity decreases, a Q-value, which is a value of a quality factor Q, decreases.

### SUMMARY

A vibrator according to the present disclosure for solving the problems described above is a vibrator using a piezoelectric body made of a zinc blende type single crystal, the vibrator including a vibrating portion which has a ring shape, and in which a plurality of first vibrating portions and a plurality of second vibrating portions are alternately arranged in at least a part of the vibrating portion, wherein the vibrating portion includes: first electrodes respectively provided to the plurality of first vibrating portions, second electrodes respectively provided to the plurality of second vibrating portions; a first coupling portion configured to electrically couple the first electrodes to each other, and a second coupling portion configured to electrically couple the second electrodes to each other, and the plurality of first electrodes and the plurality of second electrodes are alternately arranged on a plane perpendicular to a axis of the single crystal.

### BRIEF DESCRIPTION OF THE DRAWINGS

FIG. 1 is a perspective view of a cubical crystal representing a vibrator according to Embodiment 1 of the present disclosure from a (001) plane side.

FIG. 2 is a schematic diagram showing a state in which a longitudinal wave is reflected by a first reflection portion as a transverse wave, a transverse wave is reflected by a second reflection portion as a transverse wave, and a transverse wave is reflected by a third reflection portion as a longitudinal wave.

FIG. 3 is diagram showing a graph representing a relationship between an incident angle and a reflection angle, a graph representing a relationship between an incident angle and a reflection amplitude, and a graph representing a relationship between an incident angle and a phase change when a longitudinal wave is incident.

FIG. 4 is diagram showing a graph representing a relationship between an incident angle and a reflection angle, a graph representing a relationship between an incident angle and a reflection amplitude, and a graph representing a relationship between an incident angle and a phase change when a transverse wave is incident.

FIG. 5 is a perspective view illustrating a periphery of a position where a first coupling portion and a second coupling portion of the vibrator according to Embodiment 1 of the present disclosure overlap each other.

FIG. 6 is a graph showing temporal changes of voltages in a first electrode, a second electrode, and a common electrode of the vibrator according to Embodiment 1 of the present disclosure.

FIG. 7 is a schematic plan view of a part of the vibrating portion of the vibrator according to Embodiment 1 of the present disclosure and is a diagram illustrating a state when a voltage is applied.

FIG. 8 is a diagram illustrating a crystal structure of a single crystal of a piezoelectric body of the vibrator according to Embodiment 1 of the present disclosure.

FIG. 9 is a schematic view of a cubical crystal representing the vibrator according to Embodiment 1 of the present disclosure from the (001) plane side, and is a diagram illustrating a deformed state of a unit vibrator.

FIG. 10 is a schematic plan view of a vibrating portion of a vibrator according to Embodiment 2 of the present disclosure, and is a diagram illustrates a state when a voltage is applied.

FIG. 11 is a perspective view of a cubical crystal representing a vibrator according to an embodiment of the present disclosure from a (001) plane side.

FIG. 12 is a schematic view showing a state in which a transverse wave is reflected by the first reflection portion as a transverse wave, and the transverse wave is reflected by the second reflection portion as a transverse wave.

FIG. 13 is diagram showing graphs representing a relationship between an incident angle and a reflection angle, a graph representing a relationship between an incident angle and a reflection amplitude, and a graph representing a relationship between an incident angle and a phase change when a transverse wave is incident.

FIG. 14 is a plan view illustrating the periphery of a first vibrating portion and a second vibrating portion of the vibrator according to the embodiment of the present disclosure.

FIG. 15 is a perspective view illustrating a periphery of a position where a first coupling portion and a second coupling portion of the vibrator according to the embodiment of the present disclosure overlap each other.

FIG. 16 is a perspective view illustrating a periphery of a position where the first coupling portion and the second coupling portion of the vibrator according to the embodiment of the present disclosure overlap each other.

FIG. 17 is a graph showing temporal changes of voltages in a first electrode, a second electrode, and a common electrode of the vibrator according to the embodiment of the present disclosure.

FIG. 18 is a schematic plan view of a part of a vibrating portion of the vibrator according to the embodiment of the present disclosure and is a diagram illustrating a state when no voltage is applied.

FIG. 19 is a schematic plan view of a part of the vibrating portion of the vibrator according to the embodiment of the present disclosure and is a diagram illustrating a state when a voltage is applied.

FIG. 20 is a schematic plan view of a part of the vibrating portion of the vibrator according to the embodiment of the present disclosure and is a diagram illustrating a state when a voltage, which is obtained by inverting the phase of the voltage applied in FIG. 19, is applied.

### DESCRIPTION OF EMBODIMENTS

First, the present disclosure will schematically be described.

A vibrator according to a first aspect of the present disclosure for solving the problems described above is a vibrator using a piezoelectric body made of a zinc blende type single crystal, the vibrator including a vibrating portion which has a ring shape, and in which a plurality of first vibrating portions and a plurality of second vibrating portions are alternately arranged in at least a part of the vibrating portion, wherein the vibrating portion includes: first electrodes respectively provided to the plurality of first vibrating portions, second electrodes respectively provided to the plurality of second vibrating portions; a first coupling portion configured to electrically couple the first electrodes to each other, and a second coupling portion configured to electrically couple the second electrodes to each other, and the plurality of first electrodes and the plurality of second electrodes are alternately arranged on a plane perpendicular to a axis of the single crystal.

According to this aspect, a plurality of first vibrating portions and a plurality of second vibrating portions are alternately arranged in at least a part of a ring-shaped vibrating portion, and first electrodes corresponding to the first vibrating portions and second electrodes corresponding to the second vibrating portions are alternately arranged on a plane perpendicular to the axis of the single crystal in the ring-shaped vibrating portion. In this way, by adopting a configuration in which a plurality of unit vibrators is arranged in at least a part of the ring-shaped vibrating portion, it is possible to make the phases of the vibration waves generated by the respective unit vibrators coincide with each other to be circulated in the ring-shaped vibrating portion. Therefore, the vibration intensity can be increased by circulating the vibration waves, and a high Q-value can be obtained.

A vibrator according to a second aspect of the present disclosure is an aspect dependent on the first aspect, and includes a reflection portion configured to reflect a vibration generated by the vibrating portion.

According to this aspect, a reflection portion that reflects the vibration generated by the vibrating portion is provided. Therefore, it is possible to easily make the phases of the vibration waves generated by the unit vibrators coincide with each other to be circulated in the ring-shaped vibrating portion.

A vibrator according to a third aspect of the present disclosure is an aspect dependent on the second aspect, wherein the reflection portion includes a first reflection portion configured to reflect an incident longitudinal wave as a transverse wave, and a second reflection portion configured to reflect the transverse wave incident on the second reflection portion via the first reflection portion as a longitudinal wave.

According to this aspect, the reflection portion includes a first reflection portion that reflects the incident longitudinal wave as a transverse wave, and a second reflection portion that reflects the transverse wave incident via the first reflection portion as a longitudinal wave. Therefore, in the ring-like vibrating portion, it is possible to make the phases of the vibration waves generated by the unit vibrators coincide with each other to be circulated while changing from the longitudinal wave to the transverse wave and from the transverse wave to the longitudinal wave.

A vibrator according to a fourth aspect of the present disclosure is an aspect dependent on the third aspect, wherein the reflection portion includes, between the first reflection portion and the second reflection portion, a third reflection portion configured to reflect an incident transverse wave on the third reflection portion as a transverse wave.

According to this aspect, as the reflection portion, a third reflection portion which reflects the incident transverse wave as a transverse wave is provided between the first reflection portion and the second reflection portion. Therefore, the traveling direction of the transverse wave can be adjusted by the third reflection portion so as to be suitably directed from the first reflection portion to the second reflection portion.

A vibrator according to a fifth aspect of the present disclosure is an aspect dependent on the second aspect, wherein the reflection portion includes a fourth reflection portion configured to reflect an incident longitudinal wave on the fourth reflection portion as a longitudinal wave.

According to this aspect, as the reflection portion, the fourth reflection portion that reflects the incident longitudinal wave as a longitudinal wave is provided. Therefore, in the ring-shaped vibrating portion, by making the vibration waves generated by the unit vibrators coincide with each other while maintaining the state of the longitudinal wave, it is possible to make the phases of the vibration waves generated by the respective unit vibrators coincide with each other to thereby increase the intensity of the vibration waves.

A vibrator according to a sixth aspect of the present disclosure is an aspect dependent on any one of the first to fifth aspects, and includes a spacer configured to insulate the first coupling portion and the second coupling portion from each other between the first coupling portion and the second coupling portion at a position where the first coupling portion and the second coupling portion overlap each other when viewed from a direction parallel to the axis of the single crystal.

According to this aspect, at a position where the first coupling portion and the second coupling portion overlap each other when viewed from the direction parallel to the axis of the single crystal, a spacer for insulating the first coupling portion and the second coupling portion from each other is provided between the first coupling portion and the second coupling portion. Therefore, a desired voltage can be stably applied to the first electrode and the second electrode.

A vibrator according to a seventh aspect of the present disclosure is an aspect dependent on any one of the first to fifth aspects, wherein the plurality of first vibrating portions and the plurality of second vibrating portions are arranged in the piezoelectric body in parallel to a axis of the single crystal or a [−110] axis of the single crystal.

According to this aspect, the plurality of first vibrating portions and the plurality of second vibrating portions are arranged in the piezoelectric body side by side in parallel to a [110] axis of the single crystal or a [−110] axis of the single crystal. By adopting such a configuration, even when a voltage is applied to each electrode particularly effectively to vibrate the first vibrating portion and the second vibrating portion, it is possible to prevent distortion from occurring in a direction in which the first vibrating portion and the second vibrating portion are arranged side by side as a whole of the vibrating portion.

A vibrator according to an eighth aspect of the present disclosure is an aspect dependent on any one of the first to fifth aspects, and includes a base which is disposed in at least a part of a periphery of the vibrating portion when viewed from a direction parallel to the axis of the single crystal, and in which the plurality of first vibrating portions and the plurality of second portions are not disposed, and a support configured to bridge the vibrating portion and the base.

According to this aspect, there are provided a base which is disposed in at least a part of the periphery of the vibrating portion when viewed from a direction parallel to the axis of the single crystal, and in which a plurality of first vibrating portions and a plurality of second vibrating portions are not arranged, and a support which bridges the vibrating portion and the base. By adopting such a configuration, it is possible to suitably provide the vibrating portion that vibrates by applying a voltage to the electrode and the base that does not vibrate even when applying the voltage to the electrode.

A vibrator according to a ninth aspect of the present disclosure is an aspect dependent on the eighth aspect, wherein the support bridges a nodal point of the vibrating portion and the base.

According to this aspect, the support bridges the nodal point of the vibrating portion and the base. By adopting such a configuration, it is possible to bridge a region of the vibrating portion, that does not vibrate even when the vibrating portion vibrates by applying the voltage to the electrode, and the base. Therefore, it is possible to arrange that the base does not vibrate even when applying the voltage to the electrode.

A tenth aspect of the present disclosure is dependent on the eighth aspect, wherein the support extends parallel to the axis of the single crystal or the [−110] axis of the single crystal.

According to this aspect, the support extends in parallel to the [110] axis of the single crystal or the [−110] axis of the single crystal. By adopting such a configuration, it is possible to suitably bridge the vibrating portion and the base.

A vibrator according to a sixth aspect of the present disclosure is an aspect dependent on any one of the first to fifth aspects, wherein the piezoelectric body is made of any of SiC, GaN, GaAs, ZnS, CdS, and AlN.

According to this aspect, the piezoelectric body is made of any one of SiC, GaN, GaAs, ZnS, CdS, and AlN. By adopting such a configuration, a preferable piezoelectric body can be obtained.

### Embodiment 1

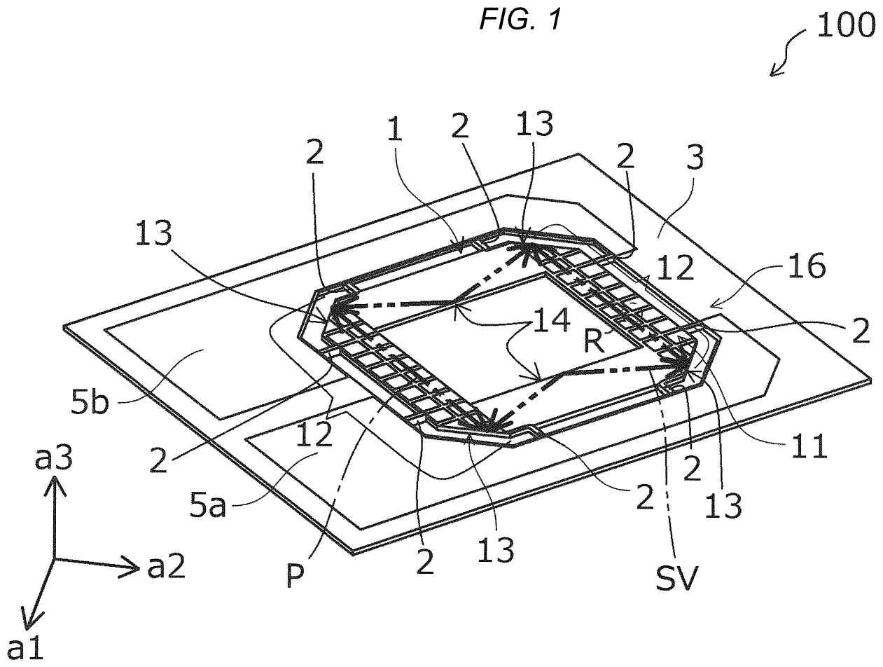

A vibrator 100 according to Embodiment 1 of the present disclosure will hereinafter be described with reference to the accompanying drawing s of FIGS. 1 to 9. The vibrator 100 according to the present embodiment is a piezoelectric vibrator using a piezoelectric body made of a zinc blende type single crystal. As shown in FIG. 1, the vibrator 100 according to the present embodiment mainly includes a vibrating portion 1 that vibrates when the voltage is applied, a base 3 that does not vibrate even when the voltage is applied, and a support 2 that bridges the vibrating portion 1 and the base 3. It should be noted that the expression “something does not vibrate even when a voltage is applied” does not mean that it does not vibrate at all in a strict sense, but means that it is sufficient to suppress the vibration to the extent that no failure occurs.

The vibrating portion 1 is formed of a substrate of a zinc blende type single crystal (point group F-43m) having a piezoelectric effect. For example, a 3C—SiC single crystal, which is a cubical crystal, can be used as the zinc blende type single crystal. Although described later in detail, the vibrating portion 1 has a ring shape, and a plurality of first vibrating portions and a plurality of second vibrating portions are adjacent to each other and are arranged alternately in the axis direction of the single crystal, in a part of the vibrating portion 1. Note that in FIGS. 1, 2, 5, 7 to 9, and 10, the a1 axis corresponds to the axis of the single crystal, the a2 axis corresponds to the axis of the single crystal, and the a3 axis corresponds to the axis of the single crystal.

The vibrating portion 1 includes an electrode group which is formed on the surface at the axis side and which includes unit electrodes 11 to correspond respectively to the unit vibrators 16 of the first vibrating portion and the second vibrating portion, two common electrodes (not shown) formed in a region corresponding to the back side of a formation region of the unit electrode 11 on the surface at the [00-1] axis side, longitudinal wave-transverse wave conversion portions 13, and total reflection portions 14. The structure formed of the electrode group on the surface at the axis side, the region of the common electrodes on the surface at the [00-1] axis side opposed to the electrode group, and the region of the single crystal substrate that generates stress due to the piezoelectric effect when a voltage is applied between these electrodes has a function as a single vibrator and constitutes the unit vibrator 16. For example, as the single crystal substrate, it is possible to use AlN, GaN, and so on belonging to a zinc blende type single crystal (point group F-43m) besides the 3C—SiC single crystal. As the material of the electrodes, for example, Au, Pt, or Al can be used, and a layer for adhesion reinforcement such as Ti or a compound thereof may be disposed between the metal material and the single crystal.

Note that in the present specification, the [100] axis may indicate the arrow direction of the a1 axis, the [−100] axis may indicate a direction opposite to the arrow direction of the a1 axis, and the [100] axis may indicate a direction along the arrow direction of the a1 axis and the opposite direction thereof in some cases. Further, the [010] axis may indicate the arrow direction of the a2 axis, the [0-10] axis may indicate a direction opposite to the arrow direction of the a2 axis, and the [010] axis may indicate a direction along the arrow direction of the a2 axis and the opposite direction thereof in some cases. Further, the [001] axis may indicate the arrow direction of the a3 axis, the [00-1] axis may indicate a direction opposite to the arrow direction of the a3 axis, and the [001] axis may indicate a direction along the arrow direction of the a3 axis and the opposite direction thereof in some cases.

An excitation portion 12 corresponding to the formation region of the unit electrode 11 has a structure in which the unit vibrators 16 are arranged in a matrix along the (001) plane of the cubical crystal. Specifically, a plurality of the unit vibrators 16 in two rows along the [−110] axis of the single crystal is arranged along the [110] axis of the single crystal. The longitudinal wave component of an elastic wave, which is generated due to the displacement of each of the unit vibrators 16 and propagates in the longitudinal direction of the excitation portion 12, that is, the [110] axis direction of the single crystal, is a traveling wave. Although described later in detail, this traveling wave is reflected by the longitudinal wave-transverse wave conversion portion 13, and further repeats the propagation and the reflection at the total reflection portion 14 to thereby circulate along the ring-shaped structure of the vibrating portion 1. Note that particularly, in addition to the traveling wave component which circulates in one direction, there is also a travelling wave component circulating in an opposite direction, and therefore, these two travelling waves interfere with each other to generate a standing wave. From the structure of the vibrating portion 1, the center position of the standing wave becomes a node.

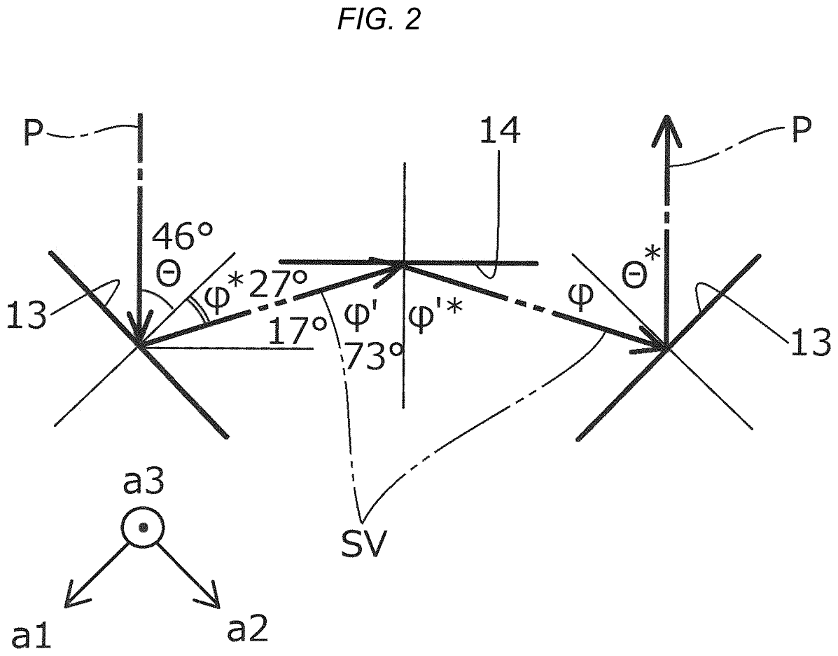

As shown in FIG. 2, the longitudinal wave-transverse wave conversion portion 13 has a planar end surface that reflects the traveling wave of the longitudinal wave P generated in the excitation portion 12 to thereby convert the traveling wave into the transverse wave SV and reflect the transverse wave SV in the direction toward the total reflection portion 14, or converts the transverse wave SV into the longitudinal wave P and reflects the longitudinal wave P toward the direction of another excitation portion 12. Here, the behavior of reflection in the longitudinal wave-transverse wave conversion portion 13 will be described below.

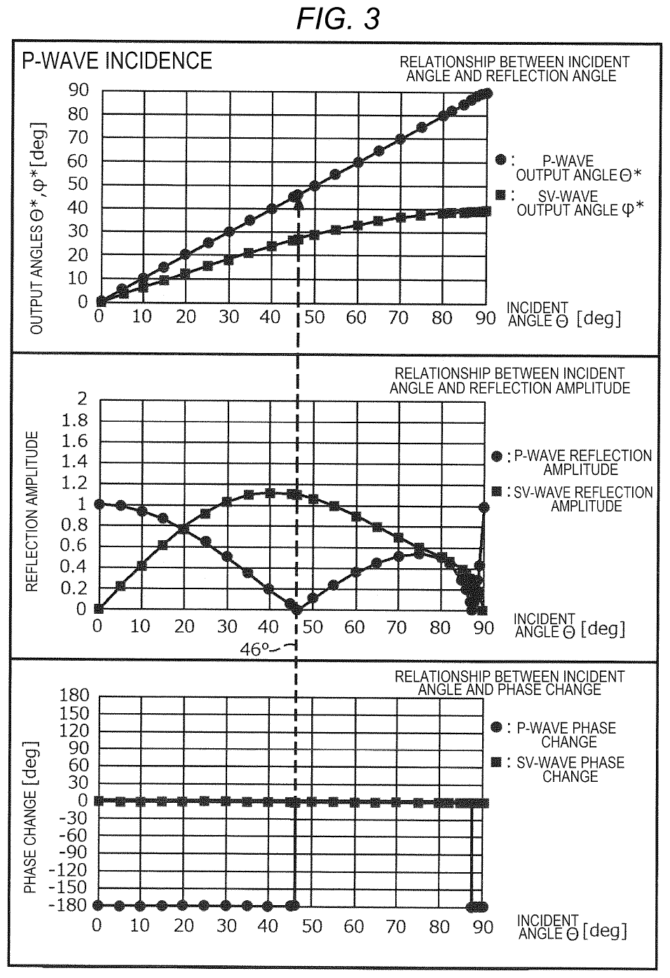

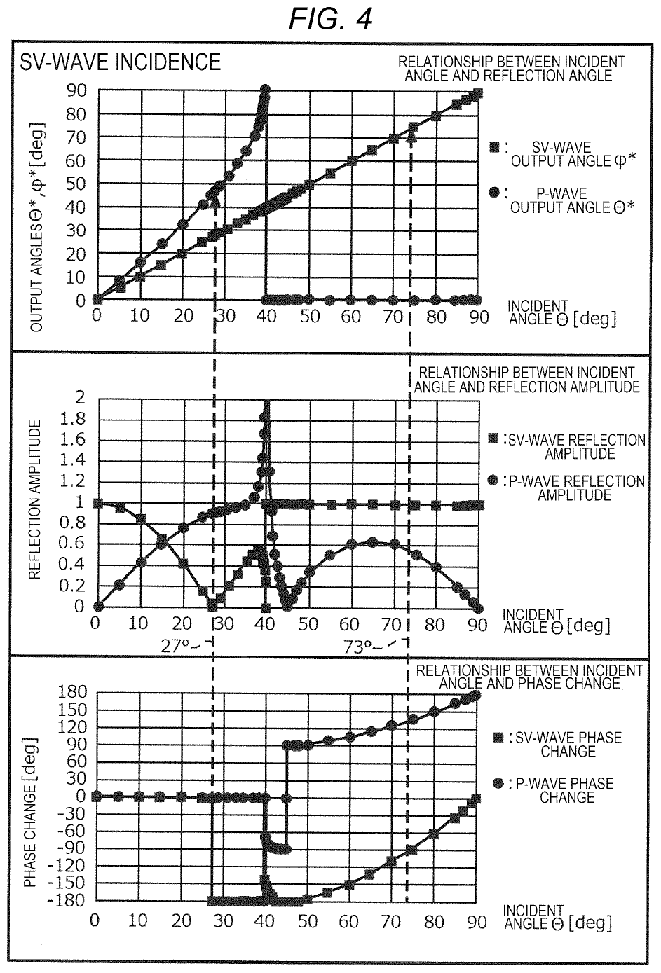

When the sound velocities of the longitudinal wave P (P wave) and the transverse wave SV (SV wave) in the crystal are represented by α and β, respectively, the values of α and β are generally different from each other. For example, typical values of 3C—SiC are α=11938 m/s and β=7608 m/s. In this case, when the longitudinal wave P is reflected by a free surface, a component of the transverse wave SV is generated, and is emitted at a different angle and is separated from the component of the longitudinal wave P. Similarly, when the transverse wave SV is reflected by a free surface, the transverse wave SV is separated into a component of the transverse wave SV and a component of the longitudinal wave P. A formula expressing the reflection amplitude and the phase change is shown in Table 1 described below. The variables used here are expressed in Formula 1 described below. FIG. 3 shows an output angle Θ* of the longitudinal wave P, an output angle φ* of the transverse wave SV, a reflection amplitude, and a phase change when the incident angle Θ of the longitudinal wave P is used as a variable. As shown in the graph in a middle part of FIG. 3, it is understood that when the incident angle @ of the longitudinal wave P is 46°, the reflection amplitude of the longitudinal wave P becomes 0, and all the vibration energy of the longitudinal wave P is converted into the transverse wave SV. As shown in FIG. 2, when θ=46°, φ* becomes φ*=27°, and the output angle φ* of the transverse wave SV is different from the incident angle θ of the longitudinal wave P. In contrast, FIG. 4 shows the output angle Θ* of the longitudinal wave P, the output angle φ* of the transverse wave SV, the reflection amplitude, and the phase change when the incident angle φ of the transverse wave SV is used as a variable. When the incident angle φ of the transverse wave SV is 27°, the reflection amplitude of the transverse wave SV becomes 0, and all the vibration energy of the transverse wave SV can be converted into the longitudinal wave P, as shown in the graph in a middle part of FIG. 4.

TABLE 1

| | P-WAVE OUTPUT | SV-WAVE OUTPUT |
|---|---|---|
| P-WAVE INCIDENCE | ${R}_{PP} = - \frac{{( {η}^{2} - {p}^{2} )}^{2} - 4 {p}^{2} ξη}{{( {η}^{2} - {p}^{2} )}^{2} + 4 {p}^{2} ξη} ,$ | ${R}_{PS} = \frac{4 p ξ ( {η}^{2} - {p}^{2} )}{{( {η}^{2} - {p}^{2} )}^{2} + 4 {p}^{2} ξη} \frac{α}{β} ,$ |
| SV-WAVE INCIDENCE | ${R}_{SP} = \frac{4 p η ( {η}^{2} - {p}^{2} )}{{( {η}^{2} - {p}^{2} )}^{2} + 4 {p}^{2} ξη} \frac{β}{α} ,$ | ${R}_{SS} = \frac{{( {η}^{2} - {p}^{2} )}^{2} - 4 {p}^{2} ξη}{{( {η}^{2} - {p}^{2} )}^{2} + 4 {p}^{2} ξη} ,$ |

$$p = \frac{sin θ}{α} = \frac{sin φ}{β} , ξ = \frac{cos θ}{α} , η = \frac{cos φ}{β} \qquad ( Formula 1 )$$

As shown in FIG. 2, the total reflection portion 14 has a plane for totally reflecting the transverse wave SV reflected and converted by the longitudinal wave-transverse wave conversion portion 13 and emitting the transverse wave SV in the direction toward the longitudinal wave-transverse wave conversion portion 13 located symmetrically to one at the incident side. As shown in FIG. 4, it is understood that the transverse wave SV is totally reflected at an incident angle φ of 73°. Note that FIG. 2 shows a positional relationship between the path and the reflection surfaces of a series of traveling waves in the longitudinal wave P-to-transverse wave SV conversion, the total reflection of the transverse wave SV, and the transverse wave SV-to-longitudinal wave P conversion.

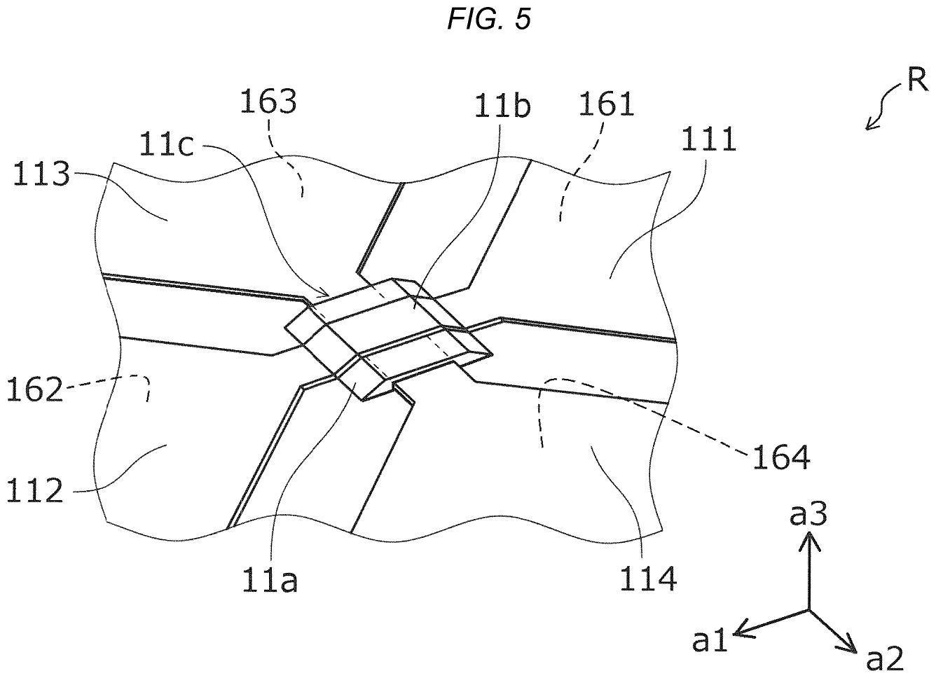

Then, an example of a coupling method of the unit electrodes 11 will hereinafter be described based on the present embodiment. In order to obtain a vibration in which the travelling waves generated from the unit vibrators 16 reinforce each other by all the unit vibrators 16 coordinating with each other, the unit electrodes 11 are coupled so that the application directions of the electric field in the axis direction become non-parallel to each other in the unit vibrators 16 adjacent to each other in the axis direction or the axis direction. In order to realize this, all the unit electrodes belong to any one of an electrode group a and an electrode group b, wherein the electrode group a corresponds to the first vibrating portion corresponding to a unit vibrator 161 and a unit vibrator 162 in FIG. 5 out of the unit vibrators 16 and the electrode group b corresponds to the second vibrating portion corresponding to a unit vibrator 163 and a unit vibrator 164 in FIG. 5 out of the unit vibrators 16.

Here, FIG. 5 shows a structure in the region R in FIG. 1 in an enlarged manner. A unit electrode 111 and a unit electrode 112 obliquely arranged on the surface of the single crystal substrate out of the unit electrodes 11 belong to the electrode group a, and are coupled to each other with a bridge portion 11b. Meanwhile, a unit electrode 113 and a unit electrode 114 out of the unit electrodes 11 belong to the electrode group b and are coupled to each other with a link portion 11c. Here, a region sandwiched between the unit electrode 111 and the common electrode of the vibrating portion 1 corresponds to the unit vibrator 161, and a region sandwiched between the unit electrode 112 and the common electrode of the vibrating portion 1 corresponds to the unit vibrator 162. Further, a region sandwiched between the unit electrode 113 and the common electrode of the vibrating portion 1 corresponds to the unit vibrator 163, and a region sandwiched between the unit electrode 114 and the common electrode of the vibrating portion 1 corresponds to the unit vibrator 164.

The link portion 11c and the bridge portion 11b are electrically insulated from each other by a spacer 11a. As the spacer 11a, an oxide such as SiO₂, a nitride, a resin material, and so on can be used. All the unit electrodes 11 belonging to the electrode group a are coupled using such a cross coupling method. Meanwhile, all the unit electrodes 11 belonging to the electrode group b are also coupled in substantially the same manner. As a result of such coupling, the unit electrodes 11 different in polarity are alternately arranged on the surface at the (001) plane side of the cubical crystal of the vibrating portion 1 to form an arrangement of a so-called checkered pattern. Further, the common electrode formed on the surface at the back surface side, which is the (00-1) plane of the cubical crystal of the vibrating portion 1, is coupled to a common electrode (not shown) disposed on the back surface of the base 3 via an electrode formed on the back surface of the support 2.

Here, the support 2 is a region for holding the vibrating portion 1 at a relative position with reference to the base 3. A single crystal substrate the same in material as the vibrating portion 1 can be used, but the support 2 may be formed by bonding other materials. In order to reduce the vibration leakage from the vibrating portion 1 to the base 3, it is desirable to set the position at which the support 2 and the vibrating portion 1 are coupled to each other to a position at which no displacement is caused by the vibration of the vibrating portion 1, that is, the position of the node. Note that it is desirable to thin the thickness of the support 2 as much as possible in order to reduce the vibration leakage from the vibrating portion 1 to the base 3, but in order to prevent the support 2 from being damaged by a vibration or an impact from the outside, it is desirable to provide the support 2 with an appropriate thickness to ensure the necessary strength. Further, although the support 2 is shown in FIG. 1 as a straight prismatic shape, in order to relax the stress concentration to improve the impact resistance, it is possible to adopt a structure in which the length is optimized, or a bent structure is mixed. Note that in the present embodiment, an electrode is formed on the surface of the support 2 so as to extend along the surface of the support 2, and also serves to electrically couple the vibrating portion 1 and the electrode formed on the base 3 to each other.

The base 3 is fixed in an airtight sealing package surrounding the piezoelectric vibrator. A single crystal substrate the same in material as the vibrating portion 1 or the support 2 can be used, but the base 3 may be formed by bonding other materials. All the unit electrodes of the electrode group a are electrically coupled to a lead electrode 5a formed on the surface of the base 3 shown in FIG. 1, via the electrode formed on the surface of the support 2. Meanwhile, all the unit electrodes of the electrode group b are electrically coupled to a lead electrode 5b shown in FIG. 1. Further, the lead electrode 5a and the lead electrode 5b are coupled to an oscillation circuit (not shown) installed in the same package by wire bonding or the like, in order to supply power to the vibrating portion 1.

In the vibrator 100 according to the present embodiment, it becomes possible to apply an electric field in the axis direction to a single crystal substrate by applying a voltage between the unit electrode 11 and the common electrode opposed to the unit electrode 11. Due to this action, the single crystal of each of the unit vibrators 16 can perform the contour vibration operation. Specifically, it corresponds to an operation in the vibration mode in which when an expansion occurs in the [110] axis direction with a certain phase, a contraction occurs in the [−110] axis direction, and when reversing the direction of the electric field, a contraction occurs in the [110] axis direction, and an expansion occurs in the [−110] axis direction. Due to the action of the contour vibration, since the expansion and the contraction occur at the same time in the directions different from each other as much as the same amount in a local portion in the single crystal substrate, a volume change does not occur, which is advantageous from the viewpoint of the thermal elastic loss and an Akhiezer loss depending on phonon scattering.

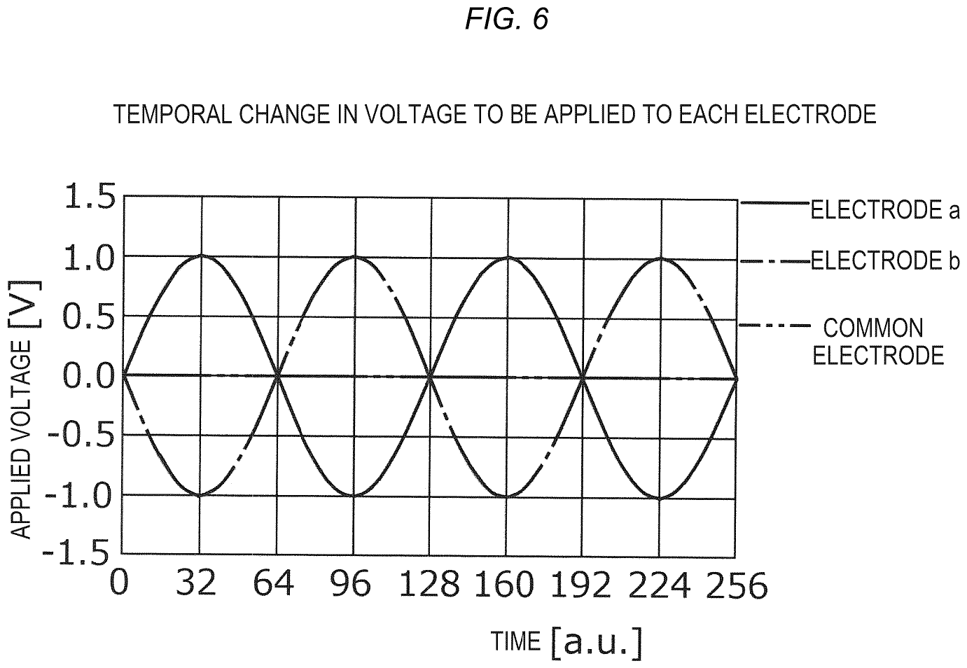

Here, FIG. 6 shows an example of a voltage waveform to be applied to the lead electrode 5a, the lead electrode 5b, and the common electrode described above. These voltage waveforms can be generated by the oscillation circuit (not shown) described above. In FIG. 6, the voltage waveform applied to the lead electrode 5a is represented by a solid line, the voltage waveform applied to the lead electrode 5b is represented by a dashed line, and the voltage waveform applied to the common electrode is represented by a two-dot chain line. The voltage waveforms to be applied to the lead electrode 5a and the lead electrode 5b are sinusoidal waves having an equal amplitude, but are shifted by a half cycle, namely n [rad] in phase from each other. The voltage applied to the common electrode is set to an average voltage of the voltages to be applied to the lead electrode 5a and the lead electrode 5b. As shown in FIG. 6, the voltage of the common electrode takes a constant value when the voltages applied to the lead electrode 5a and the lead electrode 5b are different in sign from each other and equal in amplitude.

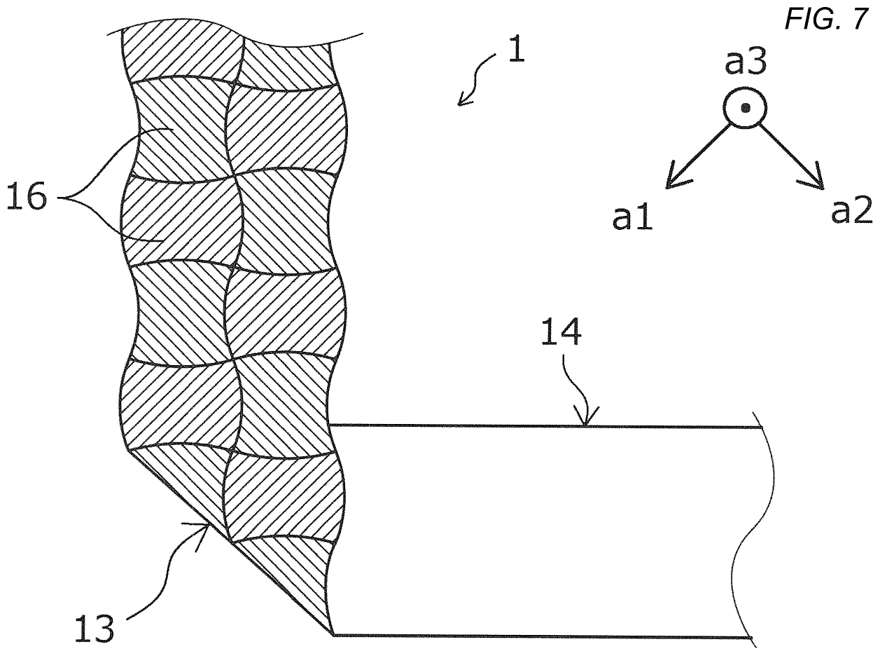

By applying the AC voltage with a frequency with which the vibrating portion 1 resonates to the lead electrode 5a and the lead electrode 5b, a desired vibration operation is possible. For example, FIG. 7 shows a displacement state which is shown with an exaggeration for making understanding easy, with respect to a corner portion of the vibrating portion 1. Here, the unit vibrators 16 corresponding to the same hatching are provided with the unit electrodes belonging to the same electrode group out of the electrode group a and the electrode group b. When no voltage is applied to both electrodes of the lead electrode 5a and the lead electrode 5b, all the unit vibrators 16 are not displaced and remain in a regular square shape, but by applying the electric fields in the same direction, the same deformation is obtained. Further, the displacement occurs by applying the voltage. When the application direction of the voltage is reversed after the time corresponding to the half cycle of the resonance elapses, the direction in which the contour of each of the unit vibrators 16 is warped is also reversed. That is, even when the application directions of the voltages continue to be alternately reversed, boundary surfaces of the unit vibrators 16 adjacent to each other have a smooth relationship in which the warpages are fit together, and unnecessary distortion does not occur.

Similarly, by repeating the reversal of the application direction of the voltages in accordance with the resonance frequency, it becomes possible for all the unit vibrators 16 to reinforce each other in a coordinated manner to obtain the vibration which is stable and low in loss. As a result, the antinodes adjacent to each other of the standing wave become opposite in phase, and thus, it is possible to obtain a stable standing wave.

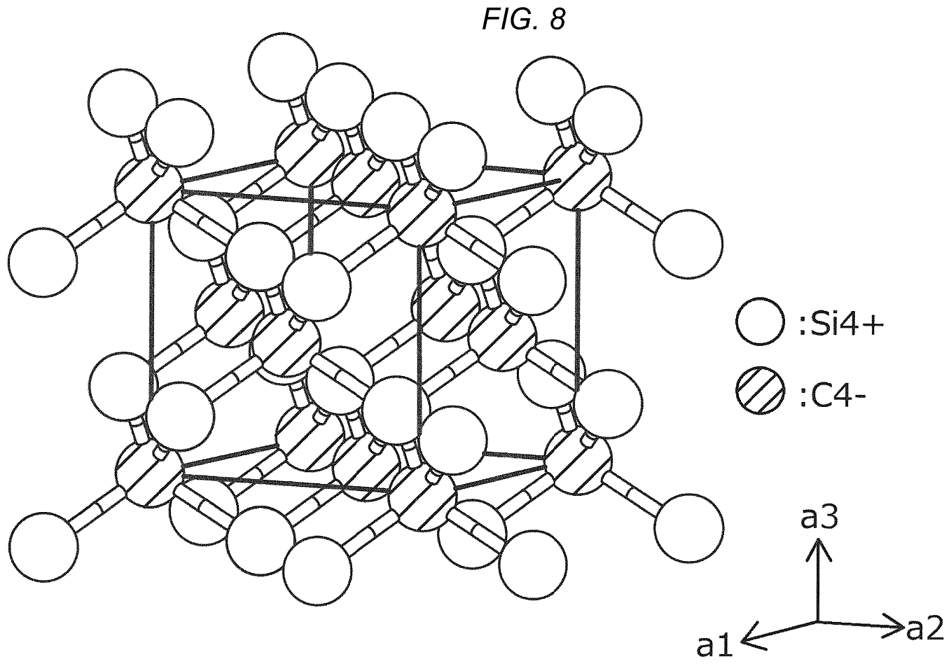

Then, an appropriate crystal orientation for realizing the vibration operation described above will be described. FIG. 8 shows a 3C—SiC crystal structure adopted in the vibrator 100 according to the present embodiment. The [100] axis of the single crystal, the [010] axis of the single crystal, and the [001] axis of the single crystal are made to correspond to the a1 axis, the a2 axis, and the a3 axis, respectively, and the displacement when an electric field is applied is confirmed.

In general, an e-type piezoelectric tensor e in the crystal of the point group F-43m is described by Formula 2 described below.

$$e = [ \begin{matrix}0 & 0 & 0 \\ 0 & 0 & 0 \\ 0 & 0 & 0 \\ {e}_{14} & 0 & 0 \\ 0 & {e}_{14} & 0 \\ 0 & 0 & {e}_{14}\end{matrix} ] \qquad ( Formula 2 )$$

Meanwhile, a d-type piezoelectric tensor d can be derived as in Formula 4 described below using Formula 3 described below which is an elastic compliance tensor SE.

$${s}^{E} = [ \begin{matrix}{s}_{11}^{E} & {s}_{12}^{E} & {s}_{12}^{E} & 0 & 0 & 0 \\ {s}_{12}^{E} & {s}_{11}^{E} & {s}_{12}^{E} & 0 & 0 & 0 \\ {s}_{12}^{E} & {s}_{12}^{E} & {s}_{11}^{E} & 0 & 0 & 0 \\ 0 & 0 & 0 & {s}_{44}^{E} & 0 & 0 \\ 0 & 0 & 0 & 0 & {s}_{44}^{E} & 0 \\ 0 & 0 & 0 & 0 & 0 & {s}_{44}^{E}\end{matrix} ] \qquad ( Formula 3 )$$

$$\begin{matrix}d = {s}^{E} \cdot e \\ = [ \begin{matrix}{s}_{11}^{E} & {s}_{12}^{E} & {s}_{12}^{E} & 0 & 0 & 0 \\ {s}_{12}^{E} & {s}_{11}^{E} & {s}_{12}^{E} & 0 & 0 & 0 \\ {s}_{12}^{E} & {s}_{12}^{E} & {s}_{11}^{E} & 0 & 0 & 0 \\ 0 & 0 & 0 & {s}_{44}^{E} & 0 & 0 \\ 0 & 0 & 0 & 0 & {s}_{44}^{E} & 0 \\ 0 & 0 & 0 & 0 & 0 & {s}_{44}^{E}\end{matrix} ] \cdot [ \begin{matrix}0 & 0 & 0 \\ 0 & 0 & 0 \\ 0 & 0 & 0 \\ {e}_{14} & 0 & 0 \\ 0 & {e}_{14} & 0 \\ 0 & 0 & {e}_{14}\end{matrix} ] \\ = [ \begin{matrix}0 & 0 & 0 \\ 0 & 0 & 0 \\ 0 & 0 & 0 \\ {s}_{44}^{E} {e}_{14} & 0 & 0 \\ 0 & {s}_{44}^{E} {e}_{14} & 0 \\ 0 & 0 & {s}_{44}^{E} {e}_{14}\end{matrix} ]\end{matrix} \qquad ( Formula 4 )$$

Here, a displacement tensor S when the electric field E having components E1, E2, and E3 in the axis directions of the a1 axis, the a2 axis, and the a3 axis, respectively, is applied can be expressed by Formula 5 described below.

$$\begin{matrix}S = d \cdot E \\ = [ \begin{matrix}0 & 0 & 0 \\ 0 & 0 & 0 \\ 0 & 0 & 0 \\ {s}_{44}^{E} {e}_{14} & 0 & 0 \\ 0 & {s}_{44}^{E} {e}_{14} & 0 \\ 0 & 0 & {s}_{44}^{E} {e}_{14}\end{matrix} ] \cdot [ \begin{matrix}{E}_{1} \\ {E}_{2} \\ {E}_{3}\end{matrix} ] \\ = [ \begin{matrix}0 \\ 0 \\ 0 \\ {s}_{44}^{E} {e}_{14} {E}_{1} \\ {s}_{44}^{E} {e}_{14} {E}_{2} \\ {s}_{44}^{E} {e}_{14} {E}_{3}\end{matrix} ]\end{matrix} \qquad ( Formula 5 )$$

Here, when an electric field is applied in the axis direction of the a3 axis, only the component E3 becomes non-zero, and therefore, only the component S6 of the displacement tensor S becomes non-zero. The definitional equation of the component S6 is expressed as Formula 6 described below.

$${S}_{6} = 2 {S}_{12} = {S}_{12} + {S}_{21} = \frac{\partial {u}_{1}}{\partial {a}_{2}} + \frac{\partial {u}_{2}}{\partial {a}_{1}} \qquad ( Formula 6 )$$

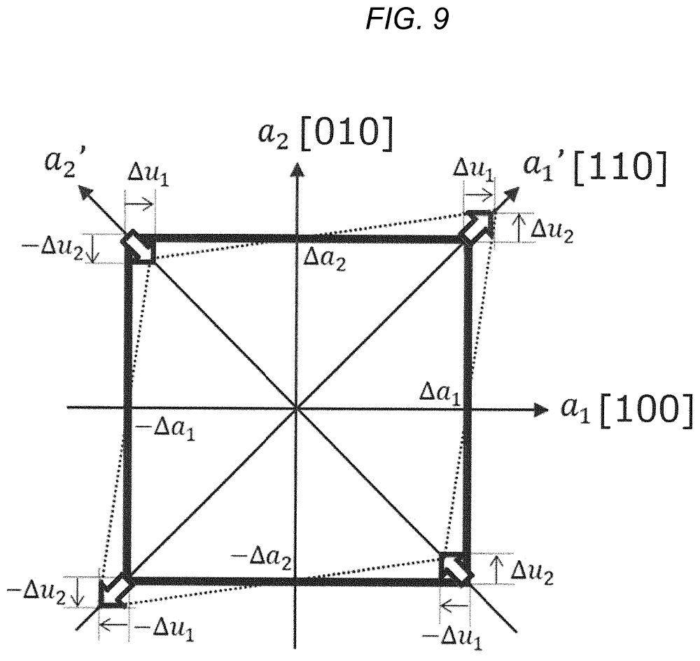

Here, u1 and u2 represent displacement amounts in the axis directions of the a1 axis and the a2 axis, respectively. Then, what deformation of the vibrating portion 1 is actually caused by the displacement amount t described above will be described with reference to FIG. 9. In particular, since the component S6 does not include the component in the axis direction of the a3 axis, the expression in a two-dimensional plane including the a1 axis and the a2 axis is used. First, from Formula 5, which is a definitional equation, Formula 7 described below is obtained, and Formula 8 described below is obtained from Formula 7.

$$2 {S}_{12} = {S}_{12} + {S}_{21} \qquad ( Formula 7 )$$

$${S}_{12} = {S}_{21} \qquad ( Formula 8 )$$

Here, assuming that the component S6 is a positive value, S12 and S21 also have positive values. The amount of change in the displacement when movement of only the minute distance +Δa1 is made from the component S12 of the formula 5, which is the definitional equation, is +Au2, and similarly, the displacement amount +Δu1 is obtained when movement of +Δa2 is made from the component S21. Further, the displacement obtained by combining these displacements is in the positive direction of the axis a1′ axis in FIG. 9. Conversely, at a position (−Δa1, −Δa2), since the displacement amount is −Δu1, −Δu2, the displacement thus combined is in the negative direction of the a1′ axis. Therefore, as a result, a micro region in the unit vibrator 16 makes an extension deformation in the axis direction of the a1′ axis.

On the other hand, a displacement in the positive direction of the a2′ axis occurs at a position (Δa1, −Δa2), and a displacement in the negative direction of that axis occurs at a position (−Δa1, Δa2), and therefore, a contraction deformation occurs in the axis direction of the a2′ axis. Thereafter, when the application direction of the voltage is reversed, the sign of the component S6 is also inverted, and the extension direction and the contraction direction are interchanged.

As described above, by assigning the [001] axis to the direction of the a3 axis shown in FIG. 1, the [110] axis to the a1′ axis direction, and the [−110] axis to the a2′ axis direction, it is possible to obtain the displacement necessary for the desired contour vibration. Further, at a point (Δa1, 0), a point (−Δa1, 0), a point (0, Δa2), and a point (0, −Δa2), a displacement is always absent while the contour vibration is made, namely there are formed nodal points of the vibration. Therefore, by disposing the support 2 in this direction, it becomes possible to suppress the vibration leaked to the base 3. Accordingly, it is desirable to dispose the support 2 in any of the directions from the centroid of any of the unit vibrators 16 to the crystal orientations [100], [−100], [010], and [0-10]. Note that as shown in FIG. 1, the vibrator 100 according to the present embodiment has such a configuration, and for example, the support 2 is provided to the unit vibrator 16 corresponding to the unit electrode 11 in the [−100] direction from the centroid thereof.

That is, in the vibrator 100 according to the present embodiment, the support 2 bridges the nodal point of the vibrating portion 1 and the base 3. By adopting such a configuration, the vibrator 100 according to the present embodiment successfully bridges a region of the vibrating portion 1 and the base 3, therein the region does not vibrate even when the vibrating portion 1 vibrates by applying the voltage to the unit electrode 11 as the electrode. Therefore, the vibrator 100 according to the present embodiment can prevent the base 3 from vibrating even when the voltage is applied to the unit electrode 11.

Further, in the description from another point of view, assuming that the support 2 bridges the nodal point of the vibrating portion 1 and the base 3, the support 2 is coupled to the four sides of the vibrating portion 1, two of the four sides are extended on the [110] axis of the single crystal, and remaining two thereof are extended in parallel to the [−110] axis of the single crystal. Since the vibrator 100 according to the present embodiment has such a configuration, the vibrating portion 1 and the base 3 are successfully bridged in a preferable manner.

Note that it is possible to configure an oscillator by combining the vibrator 100 described above and the oscillation circuit with each other. Further, by housing these in a vacuum package, it is possible to obtain a more stable oscillator. Further, although the present embodiment includes the piezoelectric body made of the 3C—SiC single crystal, a material other than the 3C—SiC single crystal may be used as long as the piezoelectric body is formed of the zinc blende type single crystal.

Here, the vibrator 100 according to the present embodiment will be described from another point of view. As described above, the vibrator 100 according to the present embodiment has the ring shape, and at least a part of the ring shape includes the vibrating portion 1 in which a plurality of first vibrating portions such as the unit vibrator 161 and the unit vibrator 162 sandwiched between the electrode group a and the common electrode, and a plurality of second vibrating portions such as the unit vibrator 163 and the unit vibrator 164 sandwiched between the electrode group b and the common electrode are alternately arranged. Further, the vibrating portion 1 includes the first electrodes which correspond to the unit electrode 111, the unit electrode 112, and so on, and are respectively provided to the plurality of first vibrating portions, second electrodes which correspond to the unit electrode 113, the unit electrode 114, and so on, and are respectively provided to the plurality of second vibrating portions, the bridge portion 11b as a first coupling portion for electrically coupling the first electrodes to each other, and the link portion 11c as a second coupling portion for electrically coupling the second electrodes to each other. Further, the plurality of first electrodes and the plurality of second electrodes are alternately arranged on a plane perpendicular to the [001] axis of the single crystal.

In this way, by adopting the configuration in which the plurality of unit vibrators 16 is arranged in at least a part of the ring-shaped vibrating portion 1, the vibrator 100 according to the present embodiment is capable of making the phases of the vibration waves generated by the respective unit vibrators 16 coincide with each other to be circulated in the ring-shaped vibrating portion 1. Therefore, the vibrator 100 according to the present embodiment is capable of increasing the vibration intensity by circulating the vibration waves, to obtain a high Q-value.

Further, as illustrated in FIG. 5, the vibrator 100 according to the present embodiment includes the spacer 11a that insulates the bridge portion 11b and the link portion 11c from each other, between the bridge portion 11b and the link portion 11c at the position where the bridge portion 11b and the link portion 11c overlap each other when viewed from a direction parallel to the [001] axis of the single crystal. Therefore, there is achieved a configuration in which a desired voltage can stably be applied to the first electrode and the second electrode.

Further, as described above, the vibrator 100 according to the present embodiment includes the longitudinal wave-transverse wave conversion portions 13 and the total reflection portions 14 as the reflection portions that reflect the vibration generated by the vibrating portion 1. Therefore, in the vibrator 100 according to the present embodiment, it is possible to make the vibration waves generated by the respective unit vibrators 16 easily coincide in phase with each other to be circulated in the ring-shaped vibrating portion 1.

Particularly, as shown in FIG. 2, as the longitudinal wave-transverse wave conversion portion 13, there are provided the first reflection portion which is located at the left side and reflects the incident longitudinal wave P as the transverse wave SV, and the second reflection portion which is located at the right side and reflects the transverse wave SV incident via the first reflection portion as the longitudinal wave P. That is, the vibrator 100 according to the present embodiment includes, as the reflection portion, the first reflection portion that reflects the incident longitudinal wave P as the transverse wave SV, and the second reflection portion that reflects the transverse wave SV incident via the first reflection portion as the longitudinal wave P. For this reason, the vibrator 100 according to the present embodiment is capable of making the vibration waves generated by the respective unit vibrators 16 coincide in phase with each other to be circulated while changing from the longitudinal wave P to the transverse wave SV, and changing from the transverse wave SV to the longitudinal wave P in the ring-shaped vibrating portion 1.

Further, as shown in FIG. 2, the vibrator 100 according to the present embodiment has, as the reflection portion, the total reflection portion 14 as the third reflection portion that reflects the incident transverse wave SV as the transverse wave SV, between the first reflection portion and the second reflection portion. Therefore, the vibrator 100 according to the present embodiment is provided with the configuration in which the traveling direction of the transverse wave SV can be adjusted with the total reflection portion 14 as the third reflection portion so as to suitably travel from the first reflection portion toward the second reflection portion.

Further, in the vibrator 100 according to the present embodiment, the plurality of first vibrating portions and the plurality of second vibrating portions are arranged in the piezoelectric body so as to be arranged in parallel to the axis of the single crystal. By adopting such a configuration, the vibrator 100 according to the present embodiment is capable of particularly effectively prevent the distortion from occurring as a whole of the vibrating portion in a direction in which the first vibrating portions and the second vibrating portions are arranged even when applying the voltage to the unit electrodes 11 to vibrate the first vibrating portions and the second vibrating portions. Note that in the present embodiment, the plurality of first vibrating portions and the plurality of second vibrating portions are arranged in the piezoelectric body in parallel to the axis of the single crystal, but it is possible to obtain substantially the same advantages with the configuration in which the plurality of first vibrating portions and the plurality of second vibrating portions are arranged in the piezoelectric body in parallel to the [−110] axis of the single crystal.

Further, the vibrator 100 according to the present embodiment is provided with the base 3 which is disposed in at least a part of the periphery of the vibrating portion 1 when viewed from a direction parallel to the [001] axis of the single crystal, and in which the plurality of first vibrating portions and the plurality of second vibrating portions are not arranged, and the support 2 which bridges the vibrating portion 1 and the base 3. Since the vibrator 100 according to the present embodiment has such a configuration, it is possible to suitably provide the vibrating portion 1 that vibrates by applying the voltage to the unit electrode 11 and the base 3 that does not vibrate even when the voltage is applied to the unit electrode 11.

Note that although the constituent material of the piezoelectric body is not particularly limited as long as the piezoelectric body is formed of the zinc blende type single crystal, the piezoelectric body is preferably made of any of SiC, GaN, GaAs, ZnS, CdS, and AlN. This is because it is possible to obtain a preferable piezoelectric body by adopting such a configuration.

As described above, by arranging the plurality of unit vibrators 16 operating in the contour vibration mode in a ring shape, it is possible to obtain a single vibration mode in which the elastic waves generated from the respective unit vibrators 16 are made to coincide in phase with each other to be circulated to thereby reinforce each other, and it is possible to obtain a high Q-value. Further, by forming the two electrode groups different in polarity on the front surface of the vibrating portion 1 and the common electrode on the back surface, alignment of the front and back surfaces is not required at the time of patterning, and productivity is improved. In addition, by using a zinc blende crystal as the single crystal substrate and installing the single crystal substrate in an appropriate crystal orientation, a strong contour vibration can be obtained. Due to the advantages described above, in the vibrator 100 according to the present embodiment, a stable and large-amplitude signal can be obtained from the vibrating portion 1, and as a result, it is possible to obtain an oscillator low in phase noise.

### Embodiment 2

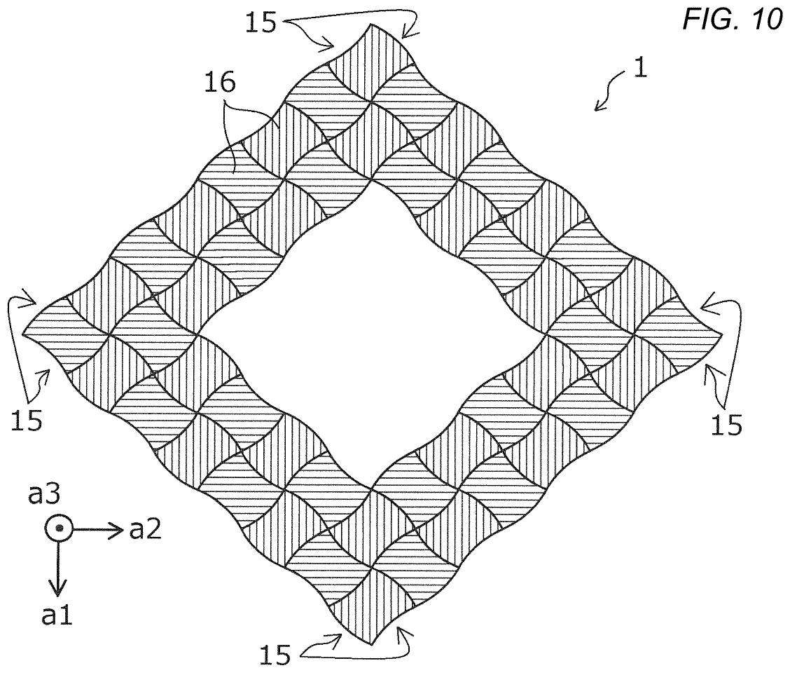

Then, a vibrator 100 according to a second embodiment will be described with reference to FIG. 10. Note that FIG. 10 is a diagram illustrating the vibrating portion 1, and the vibrator according to this embodiment has substantially the same configuration as that of the vibrator 100 according to Embodiment 1 except the points described below. In FIG. 10, the elements common to those in Embodiment 1 described above are denoted by the same reference symbols and the detailed description thereof will be omitted. The vibrator 100 according to the present embodiment has substantially the same characteristics as those of the vibrator 100 according to Embodiment 1 except the portions described below.

In the vibrator 100 according to the present embodiment, the unit electrodes 11 are formed on the entire surface at the (001) plane side of the cubical crystal of the vibrating portion 1, and the common electrode made of a solid electrode is formed on the entire surface at the (00-1) plane side of the cubical crystal of the vibrating portion 1. By adopting such a configuration, the unit vibrators 16 are formed in the entire vibrating portion 1 as shown in FIG. 10. Note that similarly to the vibrator 100 according to Embodiment 1, the plurality of first vibrating portions and the plurality of second vibrating portions are alternately arranged as the unit vibrators 16. Further, by adopting such a configuration, there is no reflection portion nor reflection surface for vertically reflecting the traveling wave. However, in corner portions 15 of the vibrating portion 1, there are unit vibrators 16 that induce a traveling wave in the [−110] axis direction of the single crystal from, for example, the traveling wave propagating in the axis direction of the single crystal, due to the contour vibration. By the actions of the unit vibrators 16, a circulating traveling wave is obtained, and stable vibration is obtained.

In the description from another point of view, the vibrator 100 according to the present embodiment has a configuration including, as a reflection portion, a fourth reflection portion which corresponds to the side of the corner portion 15 and reflects the incident longitudinal wave P as the longitudinal wave P. Therefore, the vibrator 100 according to the present embodiment is capable of making the vibration waves generated by the respective unit vibrators 16 coincide in phase to reinforce each other by combining the vibration waves generated by the respective unit vibrators 16 while keeping the state of the longitudinal wave P in the ring-shaped vibrating portion 1.

### OTHER EMBODIMENTS

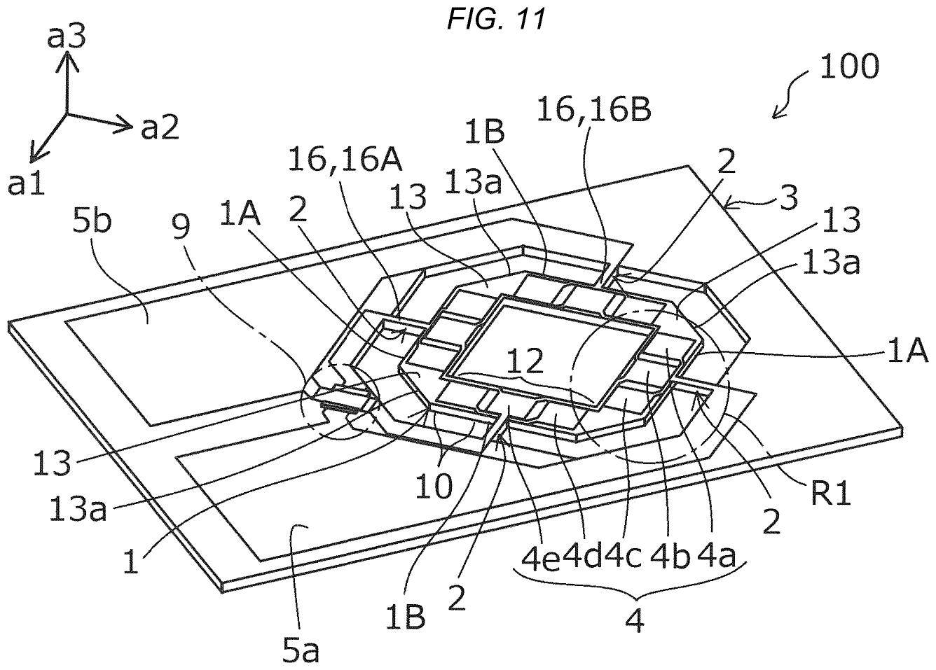

Then, a vibrator 100 according to another embodiment of the present disclosure will be described with reference to FIGS. 11 to 20. The vibrator 100 according to the present embodiment is a piezoelectric vibrator using a piezoelectric body made of the zinc blende type single crystal. As shown in FIG. 11, the vibrator 100 according to the present embodiment mainly includes the vibrating portion 1 that vibrates when the voltage is applied, the base 3 that does not vibrate even when the voltage is applied, and the support 2 that bridges the vibrating portion 1 and the base 3. It should be noted that the expression “something does not vibrate even when a voltage is applied” does not mean that it does not vibrate at all in a strict sense, but means that it is sufficient to suppress the vibration to the extent that no failure occurs.

The vibrating portion 1 is formed of a zinc blende type single crystal (point group -43m) substrate having the piezoelectric effect. For example, a crystal carved out at a predetermined cutting angle or a 3C—SiC single crystal as a cubical crystal can be used as the zinc blende type single crystal. Although described later in detail, the vibrating portion 1 has a ring shape, and the plurality of first vibrating portions and the plurality of second vibrating portions are adjacent to each other and are arranged alternately in the [100] axis direction of the single crystal and the [010] axis direction of the single crystal in a part of the vibrating portion 1. Note that in FIGS. 11, 12, 14 to 16, and 18 to 20, the a1 axis corresponds to the [100] axis of the single crystal, the a2 axis corresponds to the [010] axis of the single crystal, and the a3 axis corresponds to the [001] axis of the single crystal.

The vibrating portion 1 includes an electrode group including an unit electrode 4 including electrodes 4a, 4b, 4c, 4d, 4e and so on formed on the surface at a positive direction side of the a3 axis of the single crystal substrate having a piezoelectric effect, a solid electrode (not illustrated) formed on the back surface (at a negative direction side of the a3 axis) of the single crystal substrate, and reflection portions 13. A structure includes the electrode group on the front surface of the single crystal substrate, the solid electrode on the back surface of the single crystal substrate disposed at a position overlapping that electrode group in the direction of the a3 axis, and the region of the single crystal substrate which mainly generates shear stress due to the piezoelectric effect when a voltage is applied between the electrodes on the front surface and the back surface of the single crystal substrate, and the structure has a function as a single vibrator. That is, that structure forms unit vibrators 10.

For example, as the single crystal substrate, it is possible to use AlN, GaN, and so on belonging to a zinc blende type single crystal (point group -43m) besides the 3C—SiC single crystal. As the material of the electrodes, for example, Au, Pt, or Al can be used, and a layer for adhesion reinforcement such as Ti or a compound thereof may be disposed between the metal material and the single crystal.

Note that in the present specification, the [100] axis may indicate the arrow direction of the a1 axis, the [−100] axis may indicate a direction opposite to the arrow direction of the a1 axis, and the [100] axis may indicate a direction along the arrow direction of the a1 axis and the opposite direction thereof in some cases. Further, the [010] axis may indicate the arrow direction of the a2 axis, the [0-10] axis may indicate a direction opposite to the arrow direction of the a2 axis, and the [010] axis may indicate a direction along the arrow direction of the a2 axis and the opposite direction thereof in some cases. Further, the [001] axis may indicate the arrow direction of the a3 axis, the [00-1] axis may indicate a direction opposite to the arrow direction of the a3 axis, and the [001] axis may indicate a direction along the arrow direction of the a3 axis and the opposite direction thereof in some cases.

Note that, for example, the expression of [001] axis in the present specification is merely a representative expression, and may represent the [100] axis, the [010] axis, the [0-10] axis, the [00-1] axis, and so on in some cases in consideration of symmetry of the single crystal. Even when the designations of the directions of the single crystal are different in such a manner as described above, a structure equivalent in the geometric relationship with the arrangement direction of the unit vibrators 10 and the reflection portions 13 or the extension direction of the support 2 is also equivalent in the nature as the vibrator 100, and is therefore included in the present disclosure.

The excitation portion 12 corresponding to the formation region of the unit electrode 4 has a structure in which the unit vibrators 10 are arranged in a matrix along the a1 axis-a2 axis plane, that is, along the (001) plane of the cubical crystal. A component of f the transverse wave SV, which is generated from the shear displacement of each of the unit vibrators 10, propagates in the longitudinal direction of the excitation portion 12, that is, in the a2 direction, and elastically vibrates in the a1 axis-a2 axis plane, becomes a traveling wave. Although described later in detail, this traveling wave is totally reflected by the reflection portion 13 and circulates along the ring-shaped structure of the vibrating portion 1 by repeating the excitation and the reflection. Note that particularly, in addition to the traveling wave component which circulates in one direction, there is also a travelling wave component circulating in an opposite direction, and therefore, these two travelling waves interfere with each other to generate a standing wave. From the structure of the vibrating portion 1, the center position of the standing wave becomes a node.

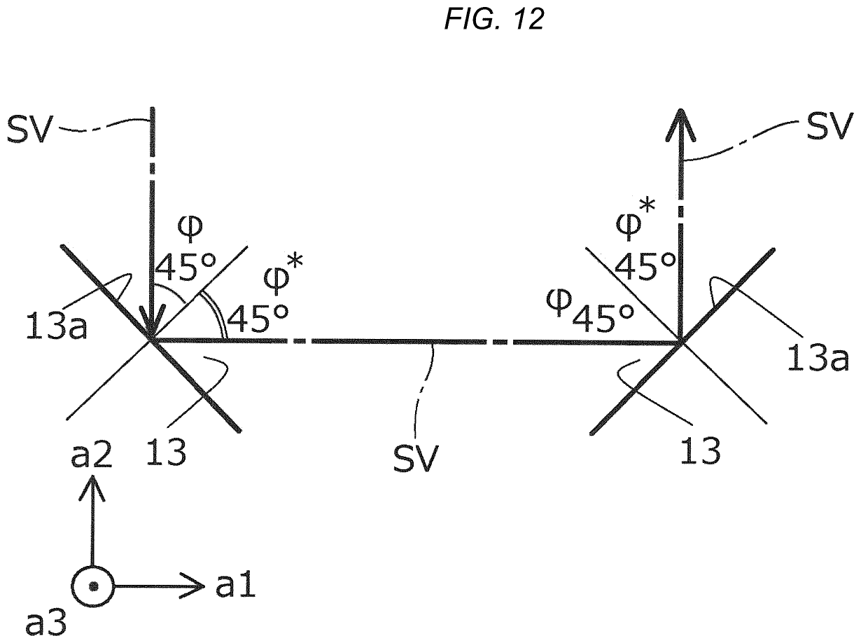

As illustrated in FIG. 12, the reflection portion 13 has a reflection surface 13a which is a planar end surface for reflecting the traveling wave of the transverse wave SV generated in the excitation portion 12 and folding the traveling wave in the direction toward the excitation portion 12 adjacent thereto as the transverse wave SV. In FIG. 12, the output angle of the transverse wave SV when the incident angle (incident angle φ) of the transverse wave SV is used as a variable is defined as the output angle φ*. Here, a behavior of the reflection at the reflection portion 13 will be described below.

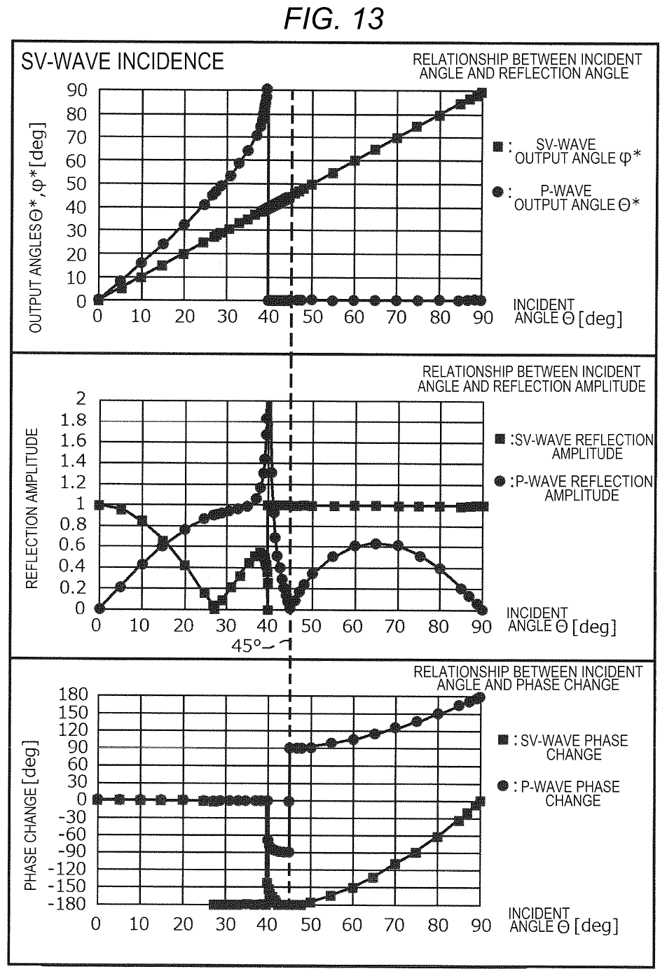

When the sound velocities of the longitudinal wave P (P wave) and the transverse wave SV (SV wave) in the crystal are represented by α and β, respectively, the values of α and β are generally different from each other. For example, typical values of 3C—SiC are α=11938 m/s and β=7608 m/s. In this case, when the longitudinal wave P is reflected by a free surface, a component of the transverse wave SV is generated, and is emitted at a different angle and is separated from the component of the longitudinal wave P. Similarly, when the transverse wave SV is reflected by a free surface, the transverse wave SV is separated into a component of the transverse wave SV and a component of the longitudinal wave P. The formula expressing the reflection amplitude and the phase change is shown in Table 1. Further, the output angle can be calculated with Formula 1, and a result of the calculation using the incident angle of the transverse wave SV as a variable is shown in the graphs in FIG. 13.

Under the condition of the sound velocity, there is also a case where a component of the longitudinal wave P is generated besides the component of the transverse wave SV. However, as represented by the graphs in the upper part and the middle part of FIG. 13, at the incident angle φ of 45°, for example, the component of the longitudinal wave P does not occur and the total reflection occurs while keeping all the vibration energy in the transverse wave SV. Further, this feature is generated when p defined by Formula 1 is equal to n as in the expressions shown in Table 1, and does not depend on the values of α and β. Further, although a phase change by −π [rad] occurs at the time of reflection, this value gently changes with respect to the incident angle φ as shown in the graph in the lower part of FIG. 13, and therefore, there is provided an advantage that the influence of the dimensional error when manufactured is small. In this way, a specific reflection behavior is exhibited when the incident angle φ is 45°. However, when actually manufacturing the vibrator 100, it is desirable to set the incident angle φ within a range of 45°±1°, that is, to be not less than 44° and not more than 46° from the allowable error of the phase change and the output angle φ* on the reflection surface 13a of the reflection portion 13.

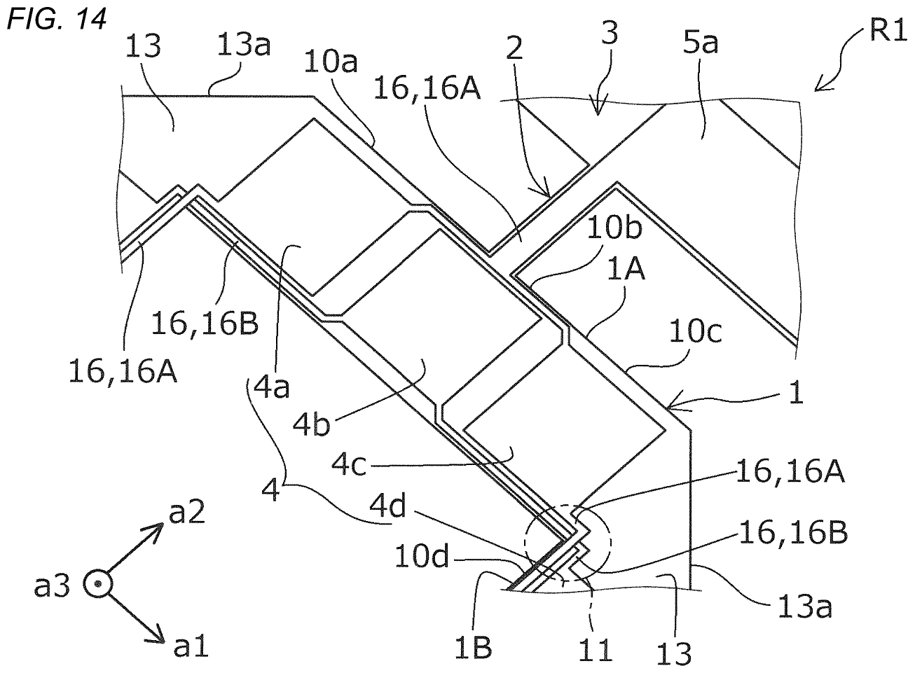

Then, an example of a coupling method of the unit electrode 4 will hereinafter be described based on the present embodiment. In order to obtain a vibration in which the travelling waves generated from the unit vibrators 10 reinforce each other by all the unit vibrators 10 coordinating with each other, the unit electrode 4 is coupled so that the application directions of the electric field in the [001] axis (the a3 axis) direction become antiparallel to each other in the unit vibrators 10 adjacent to each other in the [100] axis (the a1 axis) direction or the [010] axis (the a2 axis) direction. In order to realize this, all the unit electrodes belong to any one of an electrode group a and an electrode group b, wherein the electrode group a corresponds to the first vibrating portion corresponding to the unit vibrator 10a, the unit vibrator 10c, and so on in FIG. 14 out of the unit vibrators 10 and the electrode group b corresponds to the second vibrating portion corresponding to the unit vibrator 10b, the unit vibrator 10d, and so on in FIG. 14 out of the unit vibrators 10.

Here, FIG. 14 shows a structure in the region R1 in FIG. 11 in an enlarged manner. The electrode 4a and the electrode 4c out of the unit electrode 4 belong to the electrode group a, the electrode 4e in FIG. 11 also belongs to the electrode group a, and these electrodes are electrically coupled to the lead electrode 5a via a first coupling portion 16A as a coupling portion of the electrode group a. On the other hand, the electrode 4b and the electrode 4d out of the unit electrode 4 in FIGS. 11 and 14 belong to the electrode group b, and are electrically coupled to the lead electrode 5b via a second coupling portion 16B which is a coupling portion 16 of the electrode group b.

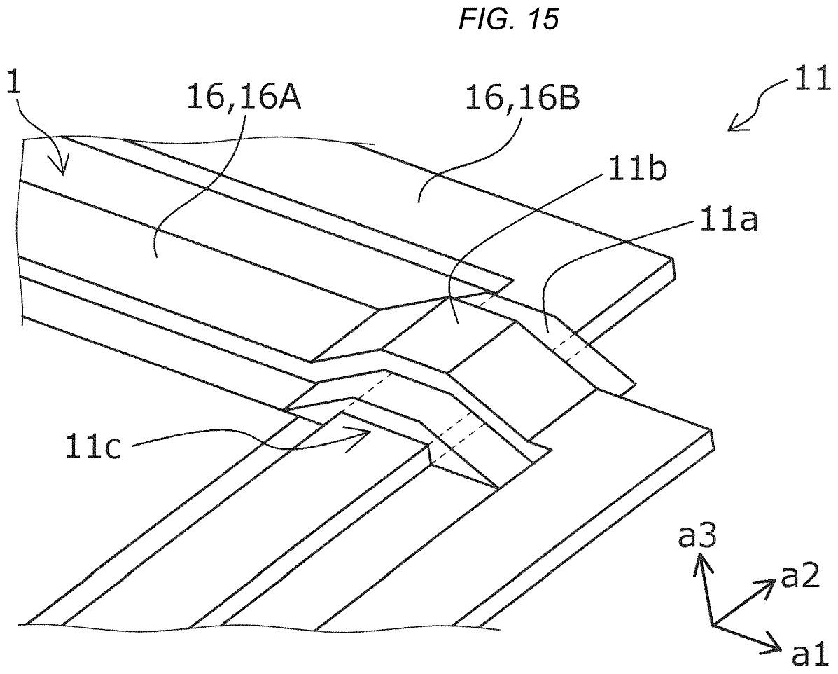

Further, FIG. 15 shows a structure of an electrode intersection portion 11 in FIG. 14 in an enlarged manner. The electrode 4b and the electrode 4d are coupled to each other with the second coupling portion 16B, and the electrode 4c and the electrode 4e are coupled to each other with the first coupling portion 16A. In the electrode intersection portion 11, the link portion 11c of the first coupling portion 16A and the bridge portion 11b of the second coupling portion 16B are electrically insulated from each other by the spacer 11a. The spacer 11a can be made of an oxide such as SiO₂, a nitride, or a resin material. All the unit electrodes 4 belonging to the electrode group a are coupled with the first coupling portion 16A using such an intersecting coupling method. Further, all the unit electrodes 4 belonging to the electrode group b are similarly coupled with the second coupling portion 16B. As a result of these coupling, the unit electrodes 4 different in polarity are alternately arranged on the (001) plane of the cubical crystal, which is the front surface of the vibrating portion 1. Further, the solid electrode formed on the (00-1) plane of the cubical crystal, which is the back surface of the vibrating portion 1, is coupled to a common electrode (not shown) of the (00-1) plane of the cubical crystal, which is the back surface of the base 3, via the coupling portion 16 formed on the (00-1) plane of the cubical crystal, which is the back surface of the support 2.

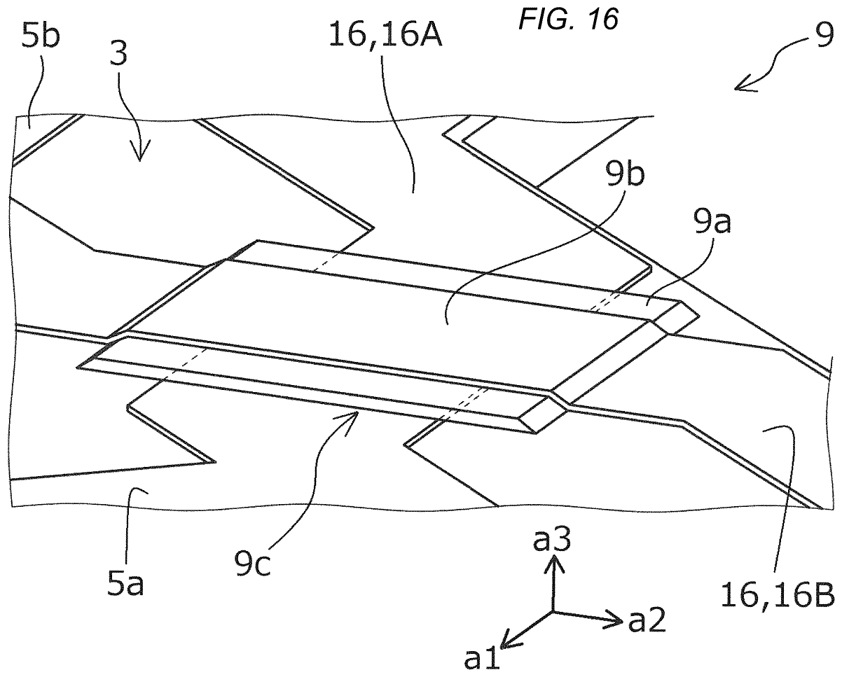

Further, FIG. 16 shows a structure of an electrode intersection portion 9 in FIG. 11 in an enlarged manner. In the electrode intersection portion 9, a link portion 9c of the first coupling portion 16A and a bridge portion 9b of the second coupling portion 16B are electrically insulated by a spacer 9a. Similarly to the spacer 11a, the spacer 9a can also be made of an oxide such as SiO₂, a nitride, or a resin material. The lead electrode 5a and all the unit electrodes 4 belonging to the electrode group a are coupled with the first coupling portion 16A using such an intersecting coupling method. Further, the lead electrode 5b and all the unit electrodes 4 belonging to the electrode group b are similarly coupled with the second coupling portion 16B.

Here, the support 2 is a region for holding the vibrating portion 1 at a relative position with reference to the base 3. A single crystal substrate the same in material as the vibrating portion 1 can be used, but the support 2 may be formed by bonding other materials. In order to reduce the vibration leakage from the vibrating portion 1 to the base 3, it is desirable to set the position at which the support 2 and the vibrating portion 1 are coupled to each other to a position at which no displacement is caused by the vibration of the vibrating portion 1, that is, the position of the node. Note that it is desirable to thin the thickness of the support 2 as much as possible in order to reduce the vibration leakage from the vibrating portion 1 to the base 3, but in order to prevent the support 2 from being damaged by a vibration or an impact from the outside, it is desirable to provide the support 2 with an appropriate thickness to ensure the necessary strength. Further, although the support 2 is shown in FIG. 11 as a straight prismatic shape, in order to relax the stress concentration to improve the impact resistance, it is possible to adopt a structure in which the length is optimized, or a bent structure is mixed. Note that in the present embodiment, an electrode is formed on the surface of the support 2 so as to extend along the surface of the support 2, and also serves to electrically couple the vibrating portion 1 and the electrode formed on the base 3 to each other.

The base 3 is fixed in an airtight sealing package surrounding the piezoelectric vibrator. A single crystal substrate the same in material as the vibrating portion 1 or the support 2 can be used, but the base 3 may be formed by bonding other materials. All the unit electrodes 4 of the electrode group a are electrically coupled to the lead electrode 5a formed on the surface of the base 3 shown in FIG. 11, via the electrode formed on the surface of the support 2. Meanwhile, all the unit electrodes 4 of the electrode group b are electrically coupled to the lead electrode 5b shown in FIG. 11. Further, the lead electrode 5a and the lead electrode 5b are coupled to an oscillation circuit (not shown) installed in the same package by wire bonding or the like, in order to supply power to the vibrating portion 1.

In the vibrator 100 according to the present embodiment, it becomes possible to apply an electric field in the axis direction (the a3 axis direction) to a single crystal substrate by applying a voltage between the unit electrode 4 and the common electrode opposed to the unit electrode 4. Due to this action, the single crystal of each of the unit vibrators 10 can perform the contour-shear vibration operation. Here, the contour-shear vibration is a vibration mode in which expansion occurs in a specific direction and contraction occurs in a direction perpendicular to the specific direction when applying an electric field corresponding to a certain phase to a certain unit vibrator 10, and contraction occurs in the specific direction and expansion occurs in the direction perpendicular to the specific direction when the direction of the electric field is reversed. Due to the action of the contour-shear vibration, since the expansion and the contraction occur at the same time in the directions different from each other as much as the same amount in a local portion in the single crystal substrate, a volume change does not occur, which is advantageous from the viewpoint of the thermal elastic loss and an Akhiezer loss depending on phonon scattering.

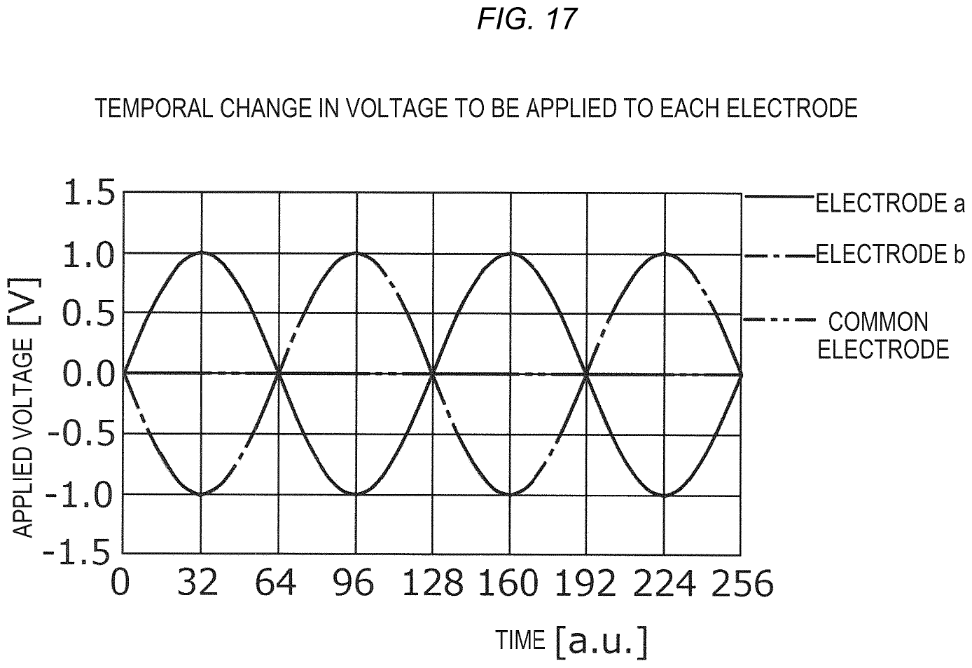

Here, FIG. 17 shows an example of voltage waveforms to be applied to the lead electrode 5a, the lead electrode 5b, and the common electrode described above. These voltage waveforms can be generated by the oscillation circuit (not shown) described above. In FIG. 17, the voltage waveform applied to the lead electrode 5a is represented by a solid line, the voltage waveform applied to the lead electrode 5b is represented by a dashed line, and the voltage waveform applied to the common electrode is represented by a two-dot chain line. The voltage waveforms to be applied to the lead electrode 5a and the lead electrode 5b are sinusoidal waves having an equal amplitude, but are shifted by a half cycle, namely n [rad] in phase from each other. The common electrode is set to an average voltage of the voltages to be applied to the lead electrode 5a and the lead electrode 5b. As shown in FIG. 17, the voltage of the common electrode takes a constant value when the voltages applied to the lead electrode 5a and the lead electrode 5b are different in sign from each other and equal in amplitude.

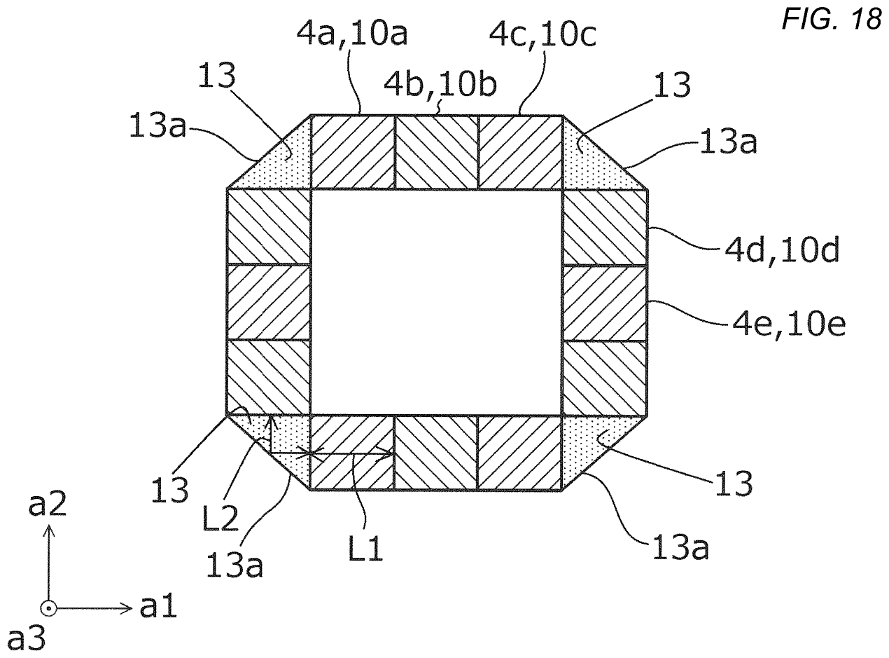

By applying the AC voltage with a frequency with which the vibrating portion 1 resonates to the lead electrode 5a and the lead electrode 5b, a desired vibration operation is possible. FIG. 18 shows the contour shape of each unit vibrator 10 when no voltage is applied between the lead electrode 5a and the lead electrode 5b. As shown in FIG. 18, the contour shape of each unit vibrator 10 on this occasion is a regular square. Here, in the unit vibrators 10 hatched in the same direction, the unit electrodes 4 belonging to the same electrode group are formed. Specifically, the unit electrodes 4 hatched with straight lines extending from the upper right to the lower left correspond to the electrode group a, and the unit electrodes 4 hatched with straight lines extending from the upper left to the lower right correspond to the electrode group b.

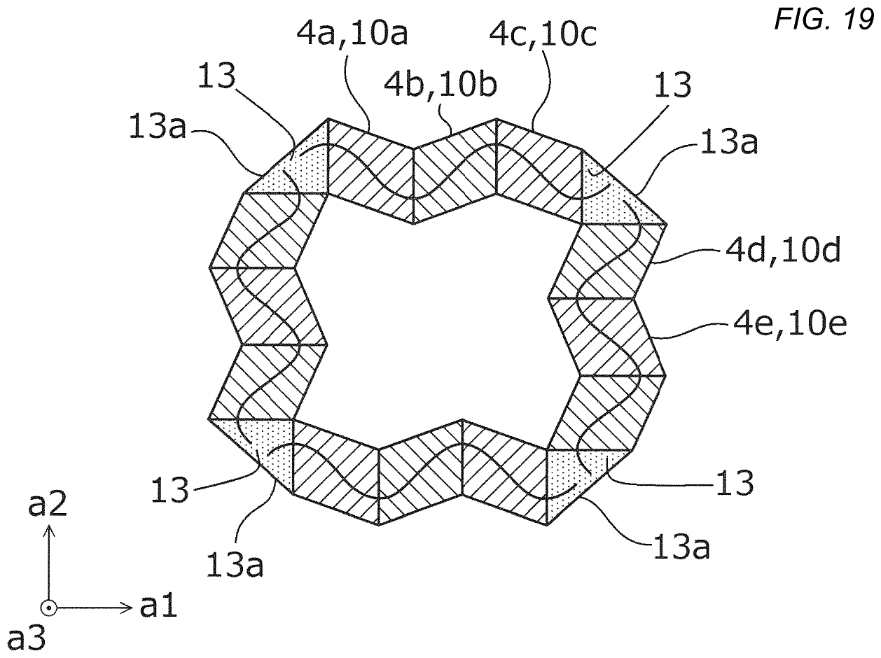

When the relative phase of the AC voltage is 0 [rad], for example, the contour of each unit vibrator 10 is displaced in a diamond shape as shown in FIG. 19 when a positive voltage is applied between the lead electrode 5a and the lead electrode 5b. This is a displacement called “contour shear.” By alternately arranging the unit vibrators 10 different in displacement direction, a wavy displacement distribution as represented by wavy lines in FIG. 19 is formed.

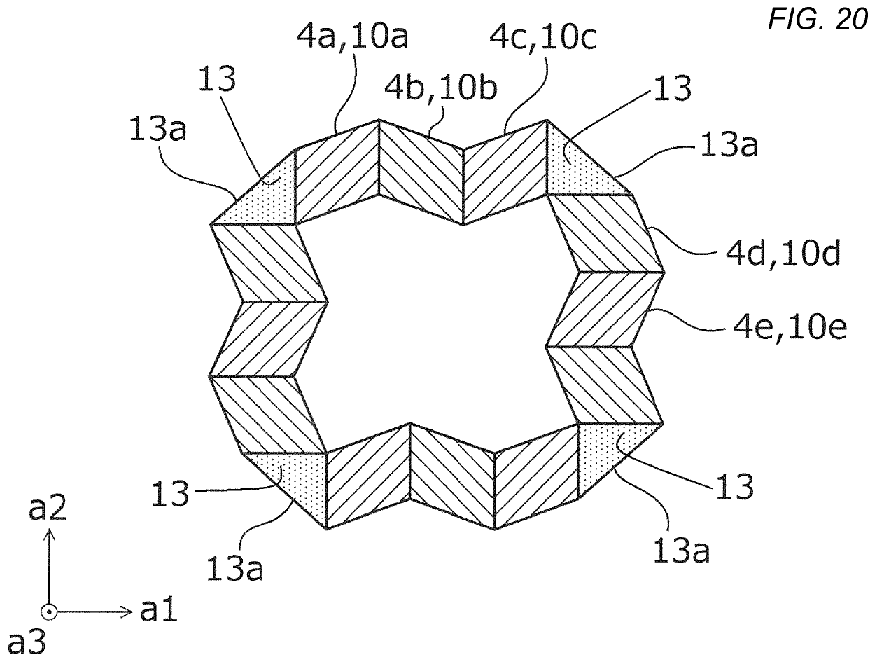

On the other hand, when the relative phase is π [rad], the voltage applied is inverted with respect to the state shown in FIG. 19. Further, it results in that a negative voltage is applied between the lead electrode 5a and the lead electrode 5b to create the state shown in FIG. 20, and the displacement distribution reversed in phase with respect to the state shown in FIG. 19 is exhibited. Note that although FIG. 19 and FIG. 20 show the diamond shapes of the individual unit vibrators 10 with exaggerations, even when the application directions of the voltages continue to be alternately reversed, boundary surfaces of the unit vibrators 10 adjacent to each other have a smooth relationship in which the warpages are fit together, and unnecessary distortion does not occur. Similarly, by repeating the reversal of the application direction of the voltages in accordance with the resonance frequency, it becomes possible for all the unit vibrators 10 to reinforce each other in a coordinated manner to obtain the vibration which is stable and low in loss. As a result, the antinodes adjacent to each other of the standing wave become opposite in phase, and thus, it is possible to obtain a stable standing wave.

Here, what polarity is appropriately provided to the unit electrodes 4 of the two unit vibrators 10 adjacent to the reflection portion 13 will be described. As described above with reference to FIG. 13, the reflection surface 13a of the reflection portion 13 receives a phase change of −π [rad]. At the same time, when converting the length of the path on which the transverse wave SV passes through the reflection portion 13, the phase change of −π [rad] is received from the propagation delay during this operation. That is, the length L1 of the path of the transverse wave SV in the unit vibrator 10 shown in FIG. 18 and the length L2 of the path of the transverse wave SV in the reflection portion 13 located between the unit vibrators 10 both correspond to a half wavelength of the wavy line shown in FIG. 19.

Therefore, a phase change of −2π [rad] occurs in the path of the transverse wave SV passing through the reflection portion 13 located between the unit vibrators 10. This means that in consideration of the periodicity of the transverse wave SV, a substantial change in phase while passing through the reflection portion 13 is equivalent to zero. Therefore, by providing the unit electrodes 4 of the two unit vibrators 10 adjacent to the reflection portion 13 with respective polarities different from each other, it becomes possible to form the transverse wave SV which continuously changes in phase. That is, as shown in FIG. 14, when the electrode 4c adjacent to the reflection portion 13 belongs to the electrode group a, it is desirable that the electrode 4d belongs to the electrode group b.

By adopting such a configuration, the transverse wave SV that advances in the clockwise direction and the counterclockwise direction when viewed from the axis direction can be induced in the ring-shaped vibrating portion 1 by applying the voltage as an AC voltage thereto to cause the displacement. When the AC frequency coincides with the resonance frequency of the vibrating portion 1, the transverse waves SV excited in all the unit vibrators 10 reinforce each other in a coordinated manner. Further, this makes it possible to obtain a standing wave stable and low in loss, that is, a contour-shear vibration.

Further, in the description from another point of view, assuming that the support 2 bridges the nodal point of the vibrating portion 1 and the base 3, the support 2 is coupled to the four sides of the vibrating portion 1, two of the four sides are extended on the [100] axis (the a1 axis) of the single crystal, and remaining two thereof are extended in parallel to the [010] axis (the a2 axis) of the single crystal. Since the vibrator 100 according to the present embodiment has such a configuration, the vibrating portion 1 and the base 3 are successfully bridged in a preferable manner.

Note that it is possible to configure an oscillator by combining the vibrator 100 described above and the oscillation circuit with each other. Further, by housing these in a vacuum package, it is possible to obtain a more stable oscillator. Further, although present the embodiment includes the piezoelectric body made of the 3C—SiC single crystal, a material other than the 3C—SiC single crystal may be used as long as the piezoelectric body is formed of the zinc blende type single crystal.

Here, the vibrator 100 according to the present embodiment will be described from another point of view. As described above, the vibrator 100 according to the present embodiment has the ring shape, and at least a part of the ring shape includes the vibrating portion 1 in which the plurality of first vibrating portions such as the unit vibrator 10a, the unit vibrator 10c, and the unit vibrator 10e, and the plurality of second vibrating portions such as the unit vibrator 10b and the unit vibrator 10d are alternately arranged. Further, the reflection portion 13 that reflects the incident transverse wave SV as a transverse wave SV is provided. Here, each of the first vibrating portions includes the first electrodes such as the electrode 4a, the electrode 4c, and the electrode 4e, and the first coupling portion 16A electrically coupling the first electrodes to each other, and each of the second vibrating portions includes the second electrodes such as the electrode 4b and the electrode 4d, and the second coupling portion 16B electrically coupling the second electrodes to each other. Further, the plurality of first electrodes and the plurality of second electrodes are alternately arranged on the plane perpendicular to the [001] axis of the single crystal, and in the vibrating portion 1, the unit vibrators 10 are arranged in the piezoelectric body in parallel to the [100] axis of the single crystal, and are arranged in the piezoelectric body in parallel to the [010] axis of the single crystal.

As described above, by adopting the configuration in which in the ring-shaped vibrating unit 1, the unit vibrators 10 are at least arranged in the piezoelectric body in parallel to the [100] axis of the single crystal or arranged in the piezoelectric body in parallel to the [010] axis of the single crystal, and further the reflection portion 13 which reflects the incident transverse wave SV as the transverse wave SV is provided, it is possible to make the vibration waves generated by the respective unit vibrators 10 coincide in phase with each other to be circulated in the ring-shaped vibrating portion 1. Therefore, the vibrator 100 according to the present embodiment having such a configuration is capable of generating the transverse waves SV, circulating the transverse waves to thereby increase the vibration intensity, and obtaining a high Q-value.

Further, in the vibrator 100 according to the present embodiment, the reflection portion 13 is disposed between the first electrodes and the second electrodes. For example, as illustrated in FIG. 14, the reflection portion 13 is disposed between the electrode 4c which is the first electrode and the electrode 4d which is the second electrode. In other words, the reflection portion 13 is disposed adjacent to one of the first vibrating portion and the second vibrating portion at the incident side of the transverse wave SV, and is disposed adjacent to the other of the first vibrating portion and the second vibrating portion at the exit side of the transverse wave SV. Since such a configuration is adopted, the vibrator 100 according to the present embodiment can reflect the transverse wave SV incident from one of the first vibrating portion and the second vibrating portion to the other of the first vibrating portion and the second vibrating portion as the transverse wave SV. That is, since such a configuration is adopted, the vibrator 100 according to the present embodiment is capable of making the vibration waves respectively generated by the unit vibrators 10 easily coincide in phase with each other to be circulated in the ring-shaped vibrating portion 1.

Here, as shown in FIG. 11, in the vibrator 100 according to the present embodiment, the vibrating portion 1 includes a first portion 1A extending along the [100] axis of the single crystal, and a second portion 1B extending along the [010] axis of the single crystal. By adopting such a configuration, the plurality of unit vibrators 10 can efficiently be arranged in the ring-shaped vibrating portion 1, and the vibration intensity can efficiently be increased.

Here, the reflection portion 13 has a reflection surface 13a, and it can be assumed that the reflection surface 13a includes a first reflection surface that reflects the transverse wave SV incident from the first portion 1A to the second portion 1B. By adopting such a configuration, the transverse wave SV incident on the first reflection surface from the first portion 1A can efficiently be reflected by the first reflection surface to the second portion 1B as the transverse wave SV.

On the other hand, as described above, in the vibrator 100 according to the present embodiment, since the transverse wave SV can be made to circulate in the right and left directions when viewing the vibrating portion 1 from the [001] axis direction in the ring-shaped vibrating portion 1, it is possible to assume that the reflection surface 13a also functions as a second reflection surface which reflects the transverse wave SV incident from the second portion 1B to the first portion 1A. Therefore, by adopting such a configuration, the transverse wave SV incident from the first portion 1A on the first reflective surface can efficiently be reflected to the second portion 1B as the transverse wave SV, and in addition, the transverse wave SV incident from the second portion 1B on the second reflective surface can efficiently be reflected to the first portion 1A as the transverse wave SV.

Here, the angle formed between the reflection surface 13a and the [100] axis of the single crystal is preferably 44° or more and 46° or less. This is because by adopting such a configuration, the longitudinal wave P can be prevented from occurring, the transverse wave SV incident from the first portion 1A on the first reflective surface can particularly efficiently be reflected to the second portion 1B as the transverse wave SV, and further, the transverse wave SV incident from the second portion 1B on the second reflective surface can particularly efficiently be reflected to the first portion 1A as the transverse wave SV.

Further, as illustrated in FIG. 15, the vibrator 100 according to the present embodiment includes the spacer 11a, that insulates the first coupling portion 16A and the second coupling portion 16B from each other, between the first coupling portion 16A and the second coupling portion 16B, in the electrode intersection portion 11 at which the first coupling portion 16A and the second coupling portion 16B overlap each other when viewed from a direction parallel to the [001] axis of the single crystal. Therefore, the vibrator 100 according to the present embodiment can stably apply a desired voltage to the first electrode and the second electrode.

Further, as illustrated in FIG. 16, the vibrator 100 according to the present embodiment includes the spacer 9a, that insulates the first coupling portion 16A and the second coupling portion 16B from each other, between the first coupling portion 16A and the second coupling portion 16B, in the electrode intersection portion 9 at which the first coupling portion 16A and the second coupling portion 16B overlap each other when viewed from a direction parallel to the [001] axis of the single crystal. Therefore, the vibrator 100 according to the present embodiment can stably apply a desired voltage to the first electrode and the second electrode.

Further, the vibrator 100 according to the present embodiment is provided with the base 3 which is disposed in at least a part of the periphery of the vibrating portion 1 when viewed from a direction parallel to the [001] axis of the single crystal, and in which the plurality of first vibrating portions and the plurality of second vibrating portions are not arranged, and the support 2 which bridges the vibrating portion 1 and the base 3. Since the vibrator 100 according to the present embodiment has such a configuration, it is possible to suitably provide the vibrating portion 1 that vibrates by applying the voltage to the unit electrode 4 and the base 3 that does not vibrate even when the voltage is applied to the unit electrode 4.

Note that although the constituent material of the piezoelectric body is not particularly limited as long as the piezoelectric body is formed of the zinc blende type single crystal, the piezoelectric body is preferably made of any of SiC, GaN, GaAs, ZnS, CdS, and AlN. This is because it is possible to obtain a preferable piezoelectric body by adopting such a configuration.

As described above, by arranging the plurality of unit vibrators 10 operating in the contour vibration mode in a ring shape, it is possible to obtain a single vibration mode in which the elastic waves generated from the respective unit vibrators 10 are made to coincide in phase with each other to be circulated to thereby reinforce each other, and it is possible to obtain a high Q-value. Further, by forming the two electrode groups different in polarity on the front surface of the vibrating portion 1 and the common electrode on the back surface, alignment of the front and back surfaces is not required at the time of patterning, and productivity is improved. In addition, by using a zinc blende crystal as the single crystal substrate and installing the single crystal substrate in an appropriate crystal orientation, a strong contour vibration can be obtained. Due to the advantages described above, in the vibrator 100 according to the present embodiment, a stable and large-amplitude signal can be obtained from the vibrating portion 1, and as a result, it is possible to obtain an oscillator low in phase noise.

The present disclosure is not limited to the above described examples and can be implemented in various configurations without departing from the gist of the present disclosure. For example, the present disclosure can be applied to a local oscillator incorporating the vibrator 100 of each of the embodiments described above, a distance measurement system and a positioning system using the local oscillator, and the like, and it is conceivable to apply the present disclosure to an MEMS sensor high in sensitivity and so on. In order to solve a part or all of the problems described above, or to achieve a part or all of the effects described above, the technical features in the embodiments corresponding to the technical features in the respective aspects described in SUMMARY can be replaced or combined as appropriate. Further, the technical features can be deleted as appropriate, unless described as essential in the present specification.

What is claimed is:

1. A vibrator using a piezoelectric body made of a zinc blende type single crystal, the vibrator comprising:
a vibrating portion which has a ring shape, and in which a plurality of first vibrating portions and a plurality of second vibrating portions are alternately arranged in at least a part of the vibrating portion, wherein
the vibrating portion includes first electrodes respectively provided to the plurality of first vibrating portions, second electrodes respectively provided to the plurality of second vibrating portions, a first coupling portion configured to electrically couple the first electrodes to each other, and a second coupling portion configured to electrically couple the second electrodes to each other, and
the plurality 41 first electrodes and the plurality of second electrodes are alternately arranged on a plane perpendicular to a axis of the single crystal.

2. The vibrator according to claim 1, further comprising:
a reflection portion configured to reflect a vibration generated by the vibrating portion.

3. The vibrator according to claim 2, wherein
the reflection portion includes a first reflection portion configured to reflect an incident longitudinal wave as a transverse wave, and a second reflection portion configured to reflect the transverse wave incident on the second reflection portion via the first reflection portion as a longitudinal wave.

4. The vibrator according to claim 3, wherein
the reflection portion includes, between the first reflection portion and the second reflection portion, a third reflection portion configured to reflect an incident transverse wave on the third reflection portion as a transverse wave.

5. The vibrator according to claim 2, wherein
the reflection portion includes a fourth reflection portion configured to reflect an incident longitudinal wave on the fourth reflection portion as a longitudinal wave.

6. The vibrator according to claim 1, further comprising:
a spacer configured to insulate the first coupling portion and the second coupling portion from each other between the first coupling portion and the second coupling portion at a position where the first coupling portion and the second coupling portion overlap each other in a direction parallel to the axis of the single crystal.

7. The vibrator according to claim 1, wherein
the plurality of first vibrating portions and the plurality of second vibrating portions are arranged in the piezoelectric body in parallel to a axis of the single crystal or a [−110] axis of the single crystal.

8. The vibrator according to claim 1, further comprising:
a base which is disposed in at least a part of a periphery of the vibrating portion in a direction parallel to the axis of the single crystal, and in which the plurality of first vibrating portions and the plurality of second portions are not disposed; and
a support configured to bridge the vibrating portion and the base.

9. The vibrator according to claim 8, wherein
the support bridges a nodal point of the vibrating portion and the base.

10. The vibrator according to claim 8, wherein
the support extends in parallel to a axis of the single crystal or a [−110] axis of the single crystal.

11. The vibrator according to claim 1, further comprising:
a reflection portion configured to reflect an incident transverse wave as a transverse wave, wherein
the plurality of first vibrating portions and the plurality of second vibrating portions form a unit vibrator, and
the unit vibrators are at least arranged in the piezoelectric body in parallel to a [100] axis of the single crystal, or arranged in the piezoelectric body in parallel to a [010] axis of the single crystal in the vibrating portion.

12. The vibrator according to claim 11, wherein
the reflection portion is disposed adjacent to one of the first vibrating portion and the second vibrating portion at an incident side of the transverse wave, and is disposed adjacent to another of the first vibrating portion and the second vibrating portion at an exit side of the transverse wave.

13. The vibrator according to claim 11, wherein
the vibrating portion includes a first portion extending along the [100] axis of the single crystal and a second portion extending along the [010] axis of the single crystal.

14. The vibrator according to claim 13, wherein
the reflection portion includes a first reflection surface configured to reflect the transverse wave incident from the first portion.

15. The vibrator according to claim 14, wherein
an angle formed between the first reflection surface and the [100] axis of the single crystal is not less than 44° and not more than 46°.

16. The vibrator according to claim 11, further comprising:
a spacer which is configured to insulate the first coupling portion and the second coupling portion from each other, and is disposed between the first coupling portion and the second coupling portion at a position where the first coupling portion and the second coupling portion overlap each other in a direction parallel to the [001] axis of the single crystal.

17. The vibrator according to claim 11, further comprising:
a base which is disposed in at least a part of a periphery of the vibrating portion in a direction parallel to the [001] axis of the single crystal, and in which the plurality of first vibrating portions and the plurality of second vibrating portions are not arranged; and
a support configured to bridge the vibrating portion and the base.

18. The vibrator according to claim 17, wherein
the support bridges a nodal point of the vibrating portion and the base.

19. The vibrator according to claim 17, wherein
the support extends in parallel to the axis of the single crystal or the [010] axis of the single crystal.

20. The vibrator according to claim 1, wherein
the piezoelectric body is made of any of SiC, GaN, GaAs, ZnS, CdS, and AlN.
